(19) United States
(12) Patent Application Publication
(10) Pub. No.: US 2009/0021996 A1
(43) Pub. Date: Jan. 22, 2009

(54) Memory Circuit, Memory Component, Data Processing System and Method of Testing a Memory Circuit

(76) Inventors: Martin Versen, Feldkirchen (DE); Helmut Schneider, Munich (DE)

Correspondence Address: SLATER & MATSIL, L.L.P., 17950 PRESTON ROAD, SUITE 1000, DALLAS, TX, 75252, US

(21) Appl. No.: 12/174,295

(22) Filed: Jul. 16, 2008

(30) Foreign Application Priority Data
Jul. 16, 2007 (DE) 10 2007 033 053.9

(51) Int. Cl. G11C 7/12; G11C 29/00

(52) U.S. Cl. 365/189.16; 365/201

(57) ABSTRACT

A memory circuit includes a plurality of bit lines and a plurality of memory cells which may be written to via a respective bit line. The memory circuit further includes a bit line control circuit. The bit line control circuit is configured to write, in a bit line-selective manner, a weak value to a memory cell coupled to a bit line selected.

This application claims priority to German Patent Application 10 2007 033 053.9, which was filed Jul. 16, 2007 and is incorporated herein by reference.

### BACKGROUND

Embodiments of the invention relate to a memory circuit, a memory component, a data processing system and a method of testing a memory circuit.

### BRIEF DESCRIPTION OF THE DRAWINGS

Embodiments of the present invention will be detailed subsequently referring to the appended drawings, in which:

FIG. 1 shows a block diagram of a memory circuit in accordance with an embodiment of the invention;

FIG. 2a shows a block diagram of a memory circuit in accordance with a further embodiment of the invention;

FIG. 2b shows a table of levels that can be used in conjunction with the circuit of FIG. 2a;

FIG. 3a shows a block diagram of a memory circuit in accordance with a further embodiment of the invention;

FIG. 3b shows a graphic representation of signals as may occur in the memory circuit in accordance with FIG. 3a;

FIG. 4a shows a circuit diagram of a precharge circuit as may be employed in a memory circuit in accordance with an embodiment of the invention;

FIG. 4b shows a graphic representation of wave forms as may occur when utilizing the precharge circuit in accordance with FIG. 4a;

FIG. 5 shows a block diagram of a bit line driver for use in a memory circuit in accordance with an embodiment of the invention;

FIG. 6 shows a block diagram of a memory circuit in accordance with a further embodiment of the invention;

FIG. 7 shows a block diagram of a memory circuit in accordance with a further embodiment of the invention;

FIG. 8 shows a schematic representation of a subarea of a memory circuit in accordance with an embodiment of the invention;

FIG. 9 shows a graphic representation of wave forms as may occur when utilizing the memory circuit in accordance with FIG. 8;

FIG. 10 shows a schematic representation of a section of a memory circuit in accordance with an embodiment of the invention;

FIG. 11 shows a schematic representation of a memory structure of a memory circuit in accordance with an embodiment of the invention;

FIG. 12 shows a schematic representation of a memory structure of a memory circuit in accordance with a further embodiment of the invention;

FIG. 13 shows a graphic representation of different signal levels;

FIG. 14 shows a flowchart of a method in accordance with an embodiment of the invention; and

FIG. 15 shows a block diagram of a data processing system in accordance with an embodiment of the invention.

### DETAILED DESCRIPTION OF ILLUSTRATIVE EMBODIMENTS

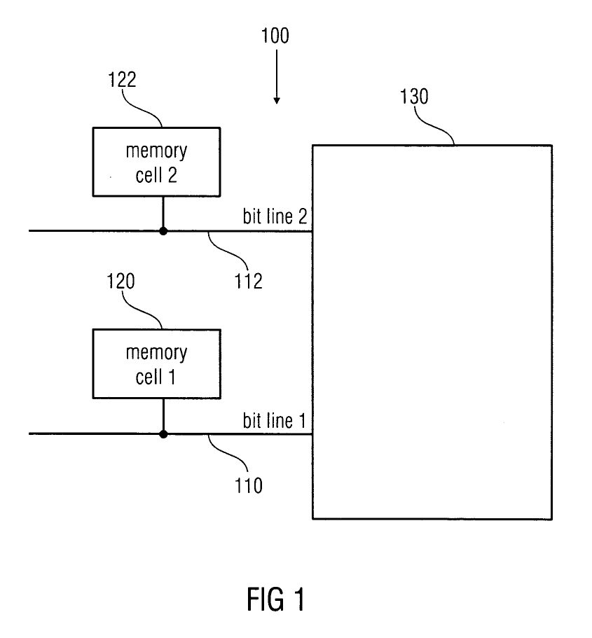

FIG. 1 shows a block diagram of a memory circuit in accordance with an embodiment of the invention. The memory circuit in accordance with FIG. 1 is designated by 100 in its entirety. The memory circuit 100 comprises a first bit line 110 (also referred to as “bit line 1”) and a second bit line 112 (also referred to as “bit line 2”). The memory circuit 100 comprises a first memory cell 120 coupled to the first bit line 110. The first memory cell 120 may also be written to via the first bit line 110 belonging to it, for example. In addition, the memory circuit 100 comprises a second memory cell 122 which is coupled to the second bit line 112 and which may also be written to via the second bit line 112 belonging to it. The memory circuit 100 further comprises a bit line control circuit 130. The bit line control circuit 130 is configured to write, in a bit line-selective manner, a weak value to a memory cell coupled to a selected bit line. For example, the bit line control circuit may write a weak value to the first memory cell 120 coupled to the first bit line 110, in which case the first bit line 110 may be regarded as the bit line selected. Alternatively, the bit line control circuit 130 may be designed, or adjusted, for example, to write a weak value to the second memory cell 122 coupled to the second bit line 112. In this case, the second bit line 112, for example, may be regarded as the bit line selected.

The bit line control circuit 130 is designed to write a weak value in a bit line-selective manner. In some embodiments this may mean that the bit line control circuit 130 may be designed, for example, to allow selecting which of the memory cells 120, 122 coupled to the bit line control circuit 130 is to have a weak value written to it. For example, the bit line control circuit 130 may be configured to receive information as to which of the memory cells 120, 122 is to have a weak value written to it. Depending on this information, the control circuit 130 may specify, for example, which of the memory cells 120, 122 is to have a weak value written to it via the bit lines 110, 112. For example, the bit line control circuit 130 may be configurable to optionally write a weak value to the first memory cell 120 or to the second memory cell 122. Alternatively, in one embodiment, the bit line control circuit 130 may also be configured to write a weak value to both memory cells 120, 122.

In some embodiments there is the possibility of configuring the bit line control circuit 130 such that in a write operation the first memory cell 120 and the second memory cell 122 are affected differently. For example, in one embodiment the bit line control circuit 130 may be configured such that a weak value is written to the first memory cell 120, whereas no weak value (but, for example, a strong value or no value at all) is written to the second memory cell 122. Further, in one embodiment the bit line control circuit 130 may be configured such that in a write operation a weak value is written to the second memory cell 122, whereas no weak value (but, for example, a strong value or no value at all) is written to the first memory cell 120. In some embodiments, the term “bit line-selective” thus describes the fact that memory cells connected to different bit lines 110, 112 are, or may be, affected differently.

The memory circuit 100 as was described with reference to FIG. 1 thus enables, for example, writing different values to two mutually corresponding memory cells 120, 122 (which are, for example, but not necessarily, coupled to the same word line). In accordance with some embodiments, the memory circuit 100 enables writing a weak value to a selected memory cell coupled to a selected bit line (e.g., to the first memory cell 120), and additionally to write a strong value to a corresponding other memory cell coupled to another bit line (e.g., to memory cell 122). Thus, some embodiments enable writing a weak value to a selected memory cell in a targeted manner, whereas strong values are written to surrounding memory cells, for example. This approach may facilitate, for example, testing of the memory circuit, or may increase the reliability of the test. Thus, some embodiments of the memory circuit 100 enable clear reduction of a test time as compared to conventional memory circuits, since the memory circuit 100 obviously enables bit line-selective writing of a weak value to a memory cell. It is thus in a particularly fast and precise manner that a memory cell may be set to a weak value suitable for a test.

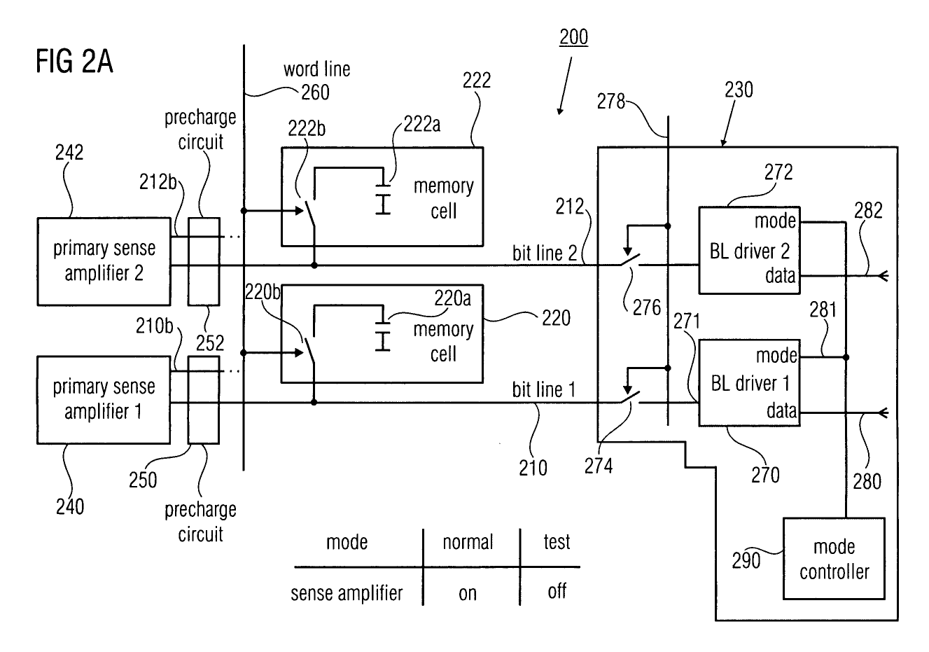

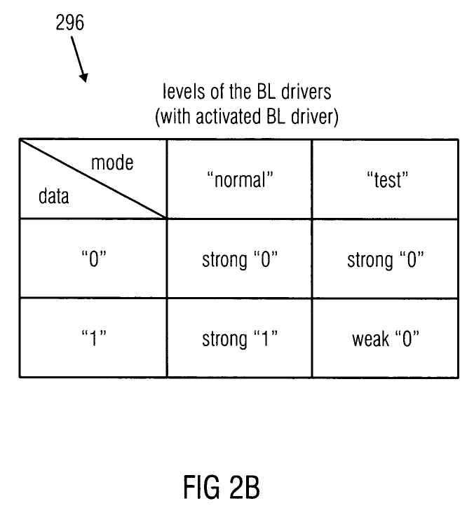

FIG. 2a shows a block diagram of a memory circuit in accordance with a further embodiment of the invention. The memory circuit in accordance with FIG. 2a is designated by 200 in its entirety. The memory circuit 200 comprises a first bit line 210 and a second bit line 212. In addition, the memory circuit 200 comprises a first memory cell 220 and a second memory cell 222. The memory circuit 200 further comprises a bit line control circuit 230 coupled, for example, to the first bit line 210 and the second bit line 212. Further, the first memory cell 220 is coupled to the first bit line 210, for example, and the second memory cell 222 is coupled to the second bit line 212, for example. The memory circuit 200 also comprises a first primary sense amplifier 240 coupled to the first bit line 210. The memory circuit 200 also comprises a second primary sense amplifier 242 coupled to the second bit line 212. The memory circuit 200 comprises a first (optional) precharge circuit 250 coupled to the first bit line 210, and a second (optional) precharge circuit 252 coupled to the second bit line 212. Also, the memory circuit 200 may be configured to be part of a dynamic random access memory (DRAM).

The mode of operation and the interaction of the individual elements of the memory circuit 200 shall be described in more detail below. The first memory cell 220 and the second memory cell 222 may be structured identically, for example. The first memory cell 220 may comprise a capacitance 220a, for example, which is coupled, e.g., to the first bit line 210 via a switch 220b. For example, the switch 220b may be switched on or off (i.e., be closed or open), depending on a state of a word line 260. Thus, all in all, the capacitor 220a of the first memory cell 220 may be coupled to the bit line 210 in an electrically effective manner via the switch 220b when the word line 260 is active.

By analogy with the first memory cell 220, the second memory cell 222 may comprise a capacitor 222a and a switch 222b which belong to it. Thus, for example, the capacitor 220a may be coupled to the second bit line 212 via the switch 222b. If the switch 222b is closed, which may be the case, for example, when the word line 260 is active, the capacitor 222a, for example, will be coupled to the second bit line 212 in an electrically effective manner. If, by contrast, the switch 222b is open (which may be the case, for example, when the word line is inactive), the capacitor 222a will be essentially disconnected from the second bit line 212. Similarly, the capacitor 220a of the first memory cell 220 is disconnected from the first bit line 210 when the word line 260 is inactive. Thus, it is to be summarized that, for example, the capacitor 220a of the first memory cell 220 and the capacitor 222a of the second memory cell 222 are coupled in an electrically effective manner to the corresponding bit lines 210, 212, respectively, as a function of a common control signal, e.g., the signal of the word line 260. Thus, for example, the first capacitor 220a is coupled to the first bit line 210 essentially during the same time period during which the second capacitor 222a is coupled to the second bit line 212.

It may thus be summarized that the first memory cell 220 and the second memory cell 222 are, for example, two memory cells which are coupled to different bit lines (the first bit line 210 and the second bit line 212) and are controlled by the same word line 260.

The bit line control circuit 230 comprises a first bit line driver 270 and a second bit line driver 272. An output of the first bit line driver 270 is or may be coupled to the first bit line 210 via a first switch 274, and the second bit line driver 272 is or may be coupled to the second bit line 212 via a second switch 276. The first switch 274 and the second switch 276 are controlled, for example, via a switch control signal 278. For example, the first switch 274 and the second switch 276 may be designed such that both switches are closed when the switch control signal 278 is active, and such that the switches mentioned are open when the switch control signal 278 is inactive.

For example, the first bit line driver 270 is configured to receive a first data signal 280 as well as a mode signal 281. The second bit line driver 272 is further configured to receive a second data signal 282 as well as the mode signal 281. The bit line control circuit 230 further comprises a mode controller 290 designed, for example, to create the mode signal 281 as a function of an operating state of the memory circuit. Also, the first bit line driver 270 and the second bit line driver 272 are, for example, designed to be essentially identical. For example, the first bit line driver 270 may be designed to provide different output levels at the output 271 as a function of the first data signal 280 and the mode signal 281, or to control the output 271 as a function of the first data signal 280 and the mode signal 281. In one embodiment, the first bit line driver 270 may be designed, for example, to take on at least three different output states, or to drive the first bit line 210 to three different voltage levels with the first switch 274 being closed, as a function of the first data signal 280 and the mode signal 281.

A potential association between the level of the first data signal 280 and the level of the mode signal 281, on the one hand, and the state of the output signal 271 of the first bit line driver 270, on the other hand, will be described below with reference to a table 296 shown in FIG. 2b. This is based on the assumption that the first data signal 280, for example, may take on at least two logic states referred to by “0” and “1”. In addition, it shall be assumed that the mode signal 281 may describe at least two different states briefly referred to as “normal” and “test” states. For example, the first bit line driver 270 is designed to generate so-called “strong” output signals, i.e., an output signal highly different from an equalize level or precharge level, in the “normal” operating state as a function of the first data signal 280. For example, the first bit line driver 270 may be configured to drive, in the “normal” operating state (indicated by the mode signal 281), the output 271 to a strong “0” if a logic level comprising the logic value of “0” is present on the first data signal 280. In addition, the first bit line driver 270 may be configured to drive the output 271 to a strong “1” if a logic level of “1” is present in the first logic signal 280. Moreover, the first bit line driver 270 may be configured to drive, in the test operating state (indicated by the mode signal 281), the output 271 on the first data signal 280 to a strong “0” if a value of logically “0” is present on the first data signal 280, and to further drive the output 271 on the first data signal 280 to a weak “0” if a logic value of “1” is present. Driving the output 271 to different levels may be realized in various manners. For example, different level drivers having different driver strengths may be used for driving, i.e., for example, transistors having different channel widths. In addition, for example, (alternatively or additionally) several different driver circuits may exist which are fed with different supply voltages so as to provide the different levels (strong “0”, strong “1”, weak “0”) at the output 271.

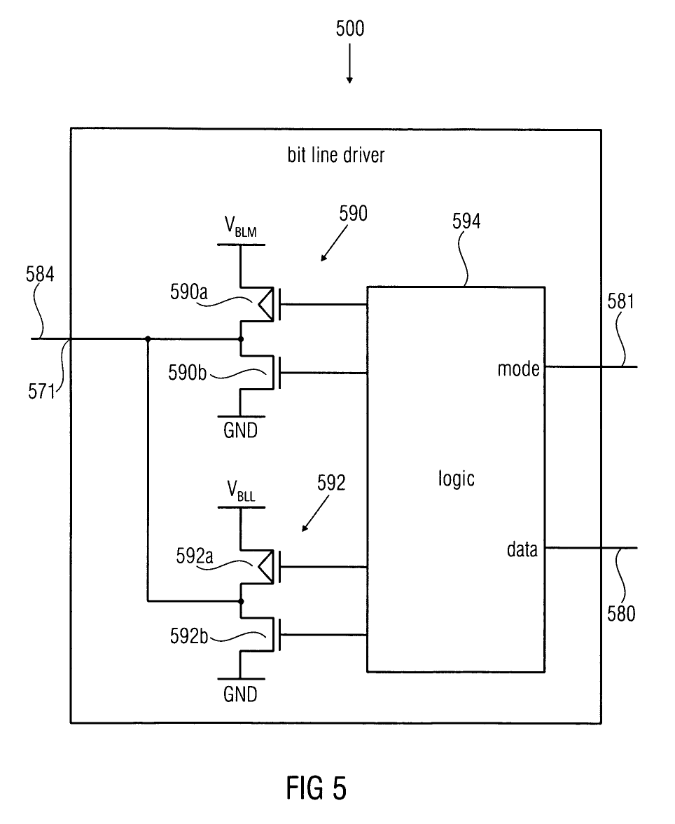

Details with regard to a potential realization of a bit line driver will be explained below with reference to FIG. 5.

Further, the second bit line driver 272 may have essentially the same functionality as the first bit line driver 270, and in some embodiments it may even be identical in structure.

To further understanding of the circuitry 200 it shall be noted that a primary sense amplifier 240, 242 is typically coupled to two bit lines. In some embodiments, a primary sense amplifier (e.g., the first primary sense amplifier 240) is coupled to a target bit line, for example the first bit line 210, as well as to a complementary bit line 210b (FIG. 2a). By analogy therewith, the second primary sense amplifier 242, for example, in one embodiment is coupled to an associated target bit line, specifically, for example, the second bit line 212, and an associated complementary bit line 212b. The target bit lines in some case will also be referred to as BLₜ below, and the complementary bit lines will be also referred to as BL_{c} below. The primary sense amplifier 240 is thus designed, in some embodiments, to amplify a potential difference between the target bit line (e.g., the first bit line 210) and the complementary bit line belonging to it (e.g., the first complementary bit line 210b). The sense amplifier may be a feedback amplifier, for example, which is designed to effect a change in the potential difference, for example, toward any of, e.g., two potential stable states, starting from an initial potential difference between the target bit line and the complementary bit line belonging to it.

With regard to the existence of the complementary bit lines 210b, 212b it is to be stated that the complementary bit lines 210b, 212b may serve, for example, as reference bit lines which are not connected to memory cells. Nevertheless, however, the complementary bit lines 210b, 212b may (optionally) also be coupled to associated bit line drivers, so that respective levels may be applied to the complementary bit lines as well, or so that the complementary bit lines may also be driven to respective levels. For this purpose, for example, in one embodiment, the respective bit line drivers (e.g., the first bit line driver 270 and the second bit line driver 272) may each comprise two outputs, one of which is coupled (for example, via a switch) to the target bit line, and a further one of which is coupled (for example, also via a switch) to the associated complementary bit line. In other words, in one embodiment the first bit line driver 270 may be extended so as to comprise, for example, the output 271 for controlling the first bit line 210, and, additionally, a further output (not shown) for controlling the associated complementary bit line 210b. By analogy therewith, the second bit line driver 272 may be extended by an additional output so as to control both the second bit line 212 and the second complementary bit line 212b optionally associated with the second bit line 212.

In addition, the memory circuit 200 may optionally comprise precharge circuits 250, 252. The first precharge circuit 250 may be coupled, for example, to the first bit line 210 so as to precharge the first bit line 210 to a desired, predetermined potential, for example, in preparation for reading out the first memory cell 220. In a further embodiment, the optional precharge circuit 250 may further be coupled both to the first bit line 210 and to the first complementary bit line 210b optionally associated with same, so as to precharge, for example, the first bit line 210 and the first complementary bit line 210b to at least approximately identical potentials. In terms of level, the respective precharge potential, or the respective precharge level (sometimes also referred to as V_{BLEQ}) may be, for example, between the level of a weak “0” and a level of a weak “1”. Details concerning this will be explained in more detail below.

In addition, it shall be noted that in one embodiment the primary sense amplifiers 240, 242 may be switched off, for example, when a weak value is written to a memory cell 220, 222. However, the functionality is to be regarded as optional. In one embodiment, for example, the first primary sense amplifier 240 and/or the second primary sense amplifier 242 may be deactivated when, for example, the mode signal 281 indicates the presence of the test mode. Alternatively, it is also possible in one embodiment that when a data value is written to a memory cell, a primary sense amplifier will be deactivated only when a weak data value (i.e., for example, a weak “0” or a weak “1”) is to be written to the respective memory cell (coupled to the sense amplifier).

With regard to the functionality of the memory circuit 200, it is further to be established that when a strong “0” is present, for example, at the output 271 of the first bit line driver 270, a strong “0” may be stored in the first memory cell 220 by closing the switch 220b, i.e. by activating the word line 260. A strong “0” here is understood to mean any voltage value or any potential that may be recognized as a logical “0” only with a comparatively high error tolerance in terms of potential during a read-out operation. However, if a weak “0” is present at the output 271 of the first bit line driver 270, a weak “0” may be stored in the memory cell 220 by closing the switch 222b. In this context, a weak “0” describes, or defines a voltage value or a potential value which may be recognized as a logical “0” only with a comparatively small error tolerance in terms of potential during a read-out operation. In other words, if it is assumed that when a value of the memory cell 220 is read out, a specific threshold value exists, a voltage level below the threshold value being recognized as a logical “0”, for example, and a voltage level above the threshold value being recognized as a logical “1”, a voltage level associated with a strong “0” is spaced further away from the threshold value than a voltage level associated with a weak “0”. A voltage level associated with a strong “1” is further away from the threshold value than a voltage level associated with a weak “1”. The respective explanations apply both to the voltage levels applied to the bit lines 210, 212 by the bit line drivers 270, 272 and to the voltage levels to which the storage capacitors 220a, 222a of the memory cells 220, 222 are charged. If, thus, a strong “0” or a strong “1” is stored in a memory cell 220, 222, the respective value stored will be readable, for example, when interferences are present, with a higher level of reliability or with a higher error tolerance in terms of potential than a weak “0” stored or a weak “1” stored.

The circuitry 200 in accordance with FIG. 2a enables controlled storage of a weak “0” or a weak “1” to a memory cell. Respective storage of the weak “0” or the weak “1” may be effected in a bit line-selective manner on account of the structure of the circuitry 200, so that, for example, memory cells coupled to adjacent bit lines (for example, to the first bit line 210 and the second bit line 212) may have different values written to them. For example, a weak “0” may be stored in the first memory cell 220, whereas a strong “0” or a strong “1” is stored in the second memory cell 222 (for example, even simultaneously). Other constellations are possible of course, for example, storing a weak “0” into the second memory cell 222 in connection with storing (possibly even simultaneously) a strong “0” or a strong “1” in the first memory cell 220. In one embodiment, individual selections may be made, by the data line 280, 282 for each of the bit lines 210, 212 as to whether a weak value (e.g., a weak “0”) or a strong value (e.g., a strong “0”) is to be stored into a corresponding memory cell 220, 222. Thus, in some embodiments there is a high level of flexibility with regard to bit line-selective storage of different values into different memory cells.

In an extended embodiment, establishing which value is to be applied to an associated bit line may be effected in a modified manner. For example, the bit line drivers 270, 272 alternatively may be designed to optionally apply a strong “0”, a weak “0”, a weak “1”, or a strong “1” to an associated bit line as a function of at least one control signal. In a further alternative embodiment, the bit line drivers 270, 272 may be designed, for example, to apply a strong “0”, a weak “1” or a strong “1” to the respectively associated bit line as a function of a mode signal and a data signal. In a further embodiment, the bit line drivers 270, 272 in accordance with FIG. 2a may further be modified to the effect that each of the bit line drivers 270, 272 receives a mode signal of its own. In this case, for example, each of the bit line drivers 270, 272 may be placed into a “normal” mode or into a “test” mode individually.

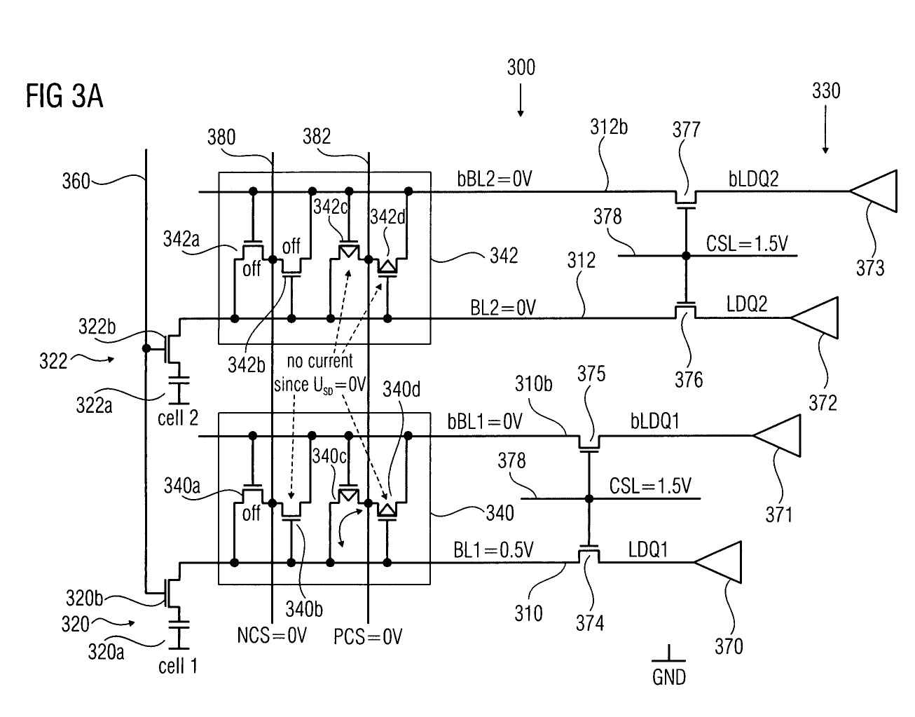

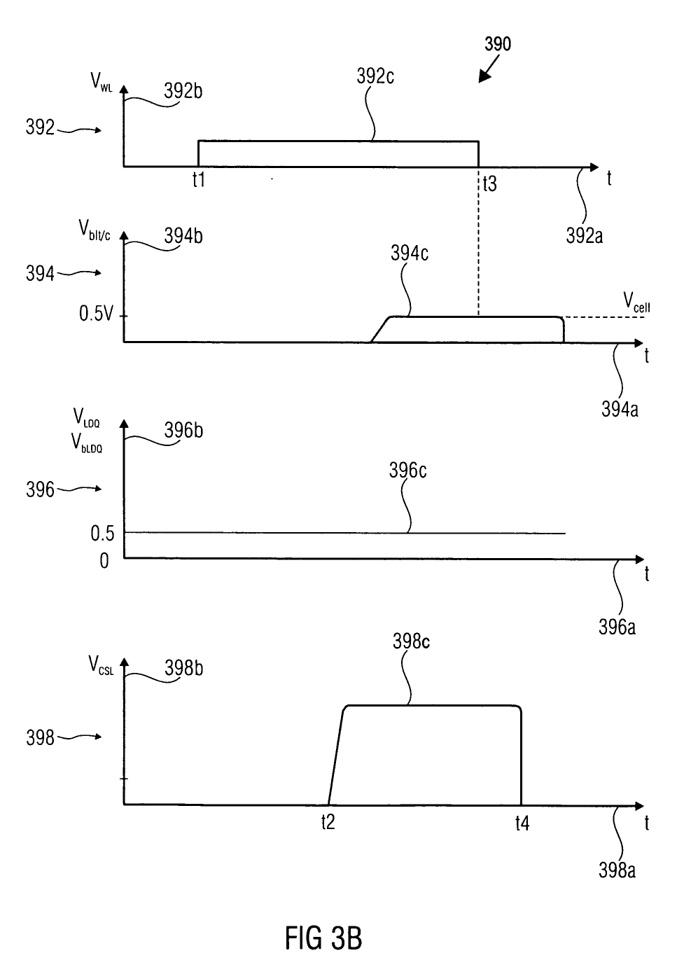

Further details with regard to the interaction of the bit line drivers 270, 272 with the associated primary sense amplifiers 240, 242 will be explained below with reference to FIG. 3a. In this context it shall be noted that the bit line drivers 270, 272 are sometimes also referred to as secondary sense amplifiers.

For explanatory purposes, FIG. 3a shows a block diagram of a memory circuit in accordance with an embodiment of the present invention. The block diagram in accordance with FIG. 3a shows a potential connection of primary and secondary sense amplifiers. The memory circuit in accordance with FIG. 3a is referred to by 300 in its entirety. The memory circuit 300 comprises a first bit line 310 as well as a first complementary bit line 310b associated with the first bit line 310. The first bit line 310 is also referred to as BL₁, and the first complementary bit line 310b is also referred to as bBL₁. The first bit line 310 essentially corresponds to the first bit line 210 in accordance with FIG. 2a as well as to the first bit line 110 in accordance with FIG. 1. Further, the first complementary bit line 310b corresponds to the first complementary bit line 210b, for example.

The memory circuit 300 further comprises a second bit line 312 and a complementary second bit line 312b associated with the second bit line 312. The second bit line 312 corresponds, for example, to the second bit line 212 in accordance with FIG. 2a as well as to the second bit line 112 in accordance with FIG. 1. Further, the complementary second bit line 312b corresponds, for example, to the second complementary bit line 212b.

The memory circuit 300 further comprises a first memory cell 320 as well as a second memory cell 322. The first memory cell 320 comprises a storage capacitance 320a coupled to the first bit line 310 via a drain-source path of an n-channel MOS field-effect transistor 320b. The second memory cell 322 comprises a respective capacitance 322a coupled to the second bit line 312 via a drain-source path of a respective n-channel MOS field-effect transistor 322b. Gate terminals of the n-channel MOS field-effect transistors 320b, 322b of the two memory cells 320, 322 are coupled to a common word line 360. The respective architecture essentially corresponds to the architecture shown in FIGS. 1 and 2.

The memory circuit 300 further comprises a bit line control circuit 330 designed to suitably control the bit lines 310, 310b, 312, 312b. In addition, the memory circuit 300 comprises a first primary sense amplifier 340 as well as a second primary sense amplifier 342. The bit line control circuit 330 comprises, for example, a first bit line driver 370, a second bit line driver 371, a third bit line driver 372, and a fourth bit line driver 373.

The first bit line driver 370 is coupled to the first bit line 310 via a switch 374 realized in the manner shown by an n-channel MOS field-effect transistor, for example. An output of the second bit line driver 371 is coupled to the complementary first bit line 310b, for example, via a second switch 375 realized, in the shown manner, for example, by an n-channel MOS field-effect transistor. The third bit line driver 372 is coupled, for example, in the manner shown, to the second bit line 312 via a third switch 376, and the fourth bit line driver 373 (or its output) is coupled to the complementary second bit line 312b, for example, via a fourth switch 377. It may thus be summarized that the outputs of the respective bit line drivers 370 to 373 are coupled in the manner shown to the respective bit line or complementary bit line via associated switches 374 to 377 (which are to be regarded as optional).

For example, the bit line drivers 370 to 373 are drivers which may drive, in each case, their respective outputs to at least three different levels, for example. In addition, the drivers mentioned may be switched, in one embodiment, between two modes of operation, it being possible for the drivers to be designed, for example, as was already described above, to provide two different levels in a first mode of operation (e.g., “normal” mode), and to further provide, in a second mode of operation (e.g., “test” mode), two further levels, at least one level in the “normal” mode differing from a corresponding level in the “test” mode.

The switches 374, 375, 376, 377 are controlled, in one embodiment, by a common switch control signal 378 also referred to as CSL.

The structure of the primary sense amplifier shall be described below. The primary sense amplifier 340 comprises, for example, a first n-channel MOS field-effect transistor 340a, a second n-channel MOS field-effect transistor 340b, a first p-channel MOS field-effect transistor 340c, and a second p-channel MOS field-effect transistor 340d. A first channel terminal of the first n-channel MOS field-effect transistor 340a is coupled to the first bit line 310, and a second channel terminal of the first n-channel MOS field-effect transistor 340a is coupled to a first sense amplifier supply line 380, which is also referred to as NCS. A first channel terminal of the second n-channel MOS field-effect transistor 340b is coupled to the complementary first bit line 310b, and a second channel terminal of the second n-channel MOS field-effect transistor 340b is coupled to the first sense amplifier supply line 380. A gate terminal of the first n-channel MOS field-effect transistor 340a is coupled to the complementary first bit line 310b, and a gate terminal of the second n-channel MOS field-effect transistor 340b is coupled to the first bit line 310. A first channel terminal of the first p-channel MOS field-effect transistor 340c is coupled to the first bit line 310, and a second channel terminal of the first p-channel MOS field-effect transistor 340c is coupled to a second sense amplifier supply line 382. A first channel terminal of the second p-channel MOS field-effect transistor 340d is coupled to the complementary first bit line 310b, and a second channel terminal of the second p-channel MOS field-effect transistor 310d is coupled to the second sense amplifier supply line 382. A gate terminal of the first p-channel MOS field-effect transistor 340c is coupled to the complementary first bit line 310b, and a gate terminal of the second p-channel MOS field-effect transistor 340d is coupled to the first bit line 310. Thus, the first sense amplifier 340 comprises a first inverter (consisting of the first n-channel MOS field-effect transistor 340a and the second p-channel MOS field-effect transistor 340c), which on the input side is coupled to the complementary first bit line 310b, on the output side is coupled to the first bit line 310, and may be supplied via the first sense amplifier supply line 380 and the second sense amplifier supply line 382. The first sense amplifier 340 further comprises a second inverter consisting of the second n-channel MOS field-effect transistor 340b and the second p-channel MOS field-effect transistor 340d, which on the input side is coupled to the first bit line 310, on the output side is coupled to the complementary first bit line 310b, and may be supplied via the first sense amplifier supply line 380 and the second sense amplifier supply line 382.

As may be seen from FIG. 3a, the second sense amplifier 342 essentially corresponds to the first sense amplifier 340 in terms of its architecture. Corresponding n-channel MOS field-effect transistors are designated by 342a and 342b, and corresponding p-channel MOS field-effect transistors are designated by 342c and 342d. It shall be noted that the second sense amplifier 342 in one embodiment is supplied via the same sense amplifier supply lines 380, 382 as the first sense amplifier 340. In other words, the first sense amplifier 340 and the second sense amplifier 342 may be activated simultaneously via the common sense amplifier supply lines 380, 382.

With reference to FIG. 3a, a state will initially be described below which may occur for writing a weak “0” to the first memory cell 320 and for (e.g., simultaneously) writing a strong “0” to the second memory cell 322.

For writing a weak “0” to the first memory cell 320 and for (e.g., simultaneously) writing a strong “0” to the second memory cell 322, the bit line drivers 370, 371, 372, 373 (which may be secondary sense amplifiers, for example), for example, may be controlled such that the first bit line driver 370 drives a level of BLL=0.5 volt at its output. The second bit line driver 371, the third bit line driver 372, and the fourth bit line driver 373 may be configured, or controlled, for example, such that the three bit line drivers mentioned each drive a level of 0 volt at their outputs. The levels mentioned here relate to a common reference potential GND in each case, for example. In addition, when writing to the memory cells 320, 322, for example, the switches 374 to 377 are closed, so that the outputs of the bit line drivers 370 to 373 are coupled to the associated bit lines 310, 310b, 312, 312b in the manner shown. For closing the switches 374 to 377, which are formed, for example, by n-channel MOS field-effect transistors, a suitable level of, e.g., 1.5 volts may be present, or be applied, at the gate terminals of the n-channel MOS field-effect transistors.

Thus, for example, the first bit line 310 is driven to the level of, e.g., 0.5 volt by the first bit line driver 370. The complementary first bit line 310b, however, is driven, for example, to a level of, e.g., about 0 volt by the second bit line driver 371. The second bit line 312 is driven, for example, to a level of 0 volt by the third bit line driver 372, and the complementary second bit line 312b is driven, for example, to a level of 0 volt by the fourth bit line driver 373. In addition, levels of, e.g., 0 volt each (NCS=0 volt; PCS=0 volt) are applied to the first sense amplifier supply line 380 and to the second sense amplifier supply line 382 in the state mentioned. Thus, a voltage of 0 volt is in each case present, for example, across the drain-source paths of the four MOS field-effect transistors 342a to 342d of the second sense amplifier 342, so that no current can flow through the MOS field-effect transistors mentioned. A voltage of 0 volt is present also across the drain-source paths of the MOS field-effect transistors 340b, 340d of the first sense amplifier 340, so that the transistors 340b, 340d mentioned will provide no current. A voltage of, e.g., 0.5 volt is present across a drain-source path of the first n-channel MOS field-effect transistor 340a. The n-channel MOS field-effect transistor 340a mentioned, however, is switched off since the gate-source voltage amounts to 0 volt, for example. In this context it is assumed that the MOS field-effect transistors are each enhancement-mode types, so that therefore, for example, the n-channel MOS field-effect transistors and the p-channel MOS field-effect transistors are non-conductive at a gate-source voltage of 0 volt. A voltage of 0.5 volt, for example, is present across a drain-source path of the first p-channel MOS field-effect transistor 340c. A gate-source voltage of the corresponding transistor also amounts to 0.5 volt, for example. Depending its threshold voltage, the first p-channel MOS field-effect transistor 340 may thus be at an operating point where current starts to flow. However, a flow of current through the first p-channel MOS field-effect transistor 340c is nearly switched off in the case of a suitable selection of the threshold voltage (and possibly in the case of a suitable setting of an associated substrate controller), so that the flow of current through the first p-channel MOS field-effect transistor 340c is sufficiently small and thus does not substantially influence the level of the first bit line 310.

In addition, it is to be stated that, in the state shown, a level of 0.5 volt is present at a drain terminal of the n-channel MOS field-effect transistor 320b of the first memory cell 320. This level may be taken over into the storage capacitor 320a of the first memory cell 320 by activation of the word line 360, so that a weak “0” is stored in the first memory cell 320. A level of 0 volt, for example, is present at a drain terminal of the n-channel MOS field-effect transistor 322b of the second memory cell 322, which level may be taken over into the storage capacitor 322a of the second memory cell 322 by activation of the word line 360. Thus, a strong “0” may be stored in the second memory cell 322 by activation of the word line 360.

Wave forms as may occur in the memory circuit 300 in accordance with FIG. 3a will be explained below with reference to FIG. 3b. For this purpose, FIG. 3b shows a graphic representation of temporal wave forms of signals as may occur in the memory circuit 300. The corresponding wave forms may also be generated, for example, by a sequential controller not shown here.

The graphic representation of FIG. 3b is designated by 390 in its entirety. A first graphic representation 392 describes a time curve of a signal on the word line 360. The time is plotted on an abscissa 392a, and a signal level present on the word line 360 is plotted on an ordinate 392b. The signal level on the word line is designated by V_{WL}, for example. A curve characteristic 392c describes the time curve of the signal level on the word line 360.

A second graphic representation 394 describes a time curve of a signal level on the first bit line 310 and on the complementary first bit line 310b. An abscissa 394a describes the time, and an ordinate 394b describes the corresponding signal levels. A level on the first bit line 310 is designated by V_{blt}, for example, and a signal level on the complementary first bit line 310b is designated by V_{blc}. A curve characteristic 394c describes a time curve of the potential on the first bit line 310, whereas the potential on the complementary first bit line 310b is permanently approximately 0, by way of example.

A third graphic representation 396 describes, for example, a time curve of a signal LDQ at the output of the first bit line driver 370, and of a signal bLDQ at the output of the second bit line driver 371. An abscissa 396a describes the time, and an ordinate 396b describes the levels of the signals LDQ and bLDQ. A curve characteristic 396c describes a time curve of the signal LDQ at the output of the first bit line driver 370. A level of the signal bLDQ at the output of the second bit line driver 371, however, is approximately steadily equal to 0 over the time period considered.

A fourth graphic representation 398 describes a time curve of the switch control signal 378 (CSL). The time is plotted on an abscissa 398a, and an ordinate 398b describes the signal level of the signal 378. A curve characteristic 398c describes the temporal development of the signal 378.

In accordance with an embodiment, it is already at the beginning of the write cycle shown in the graphic representation 390 that a suitable signal level of the signal LDQ is present at the output of the first bit line driver 370, and that further a suitable signal level of the signal bLDQ is present at the output of the second bit line driver 371. As may be seen from the graphic representation 396, the level of the signal LDQ may amount to 0.5 volt, for example, during the entire write cycle considered, whereas the level of the signal bLDQ may be steadily at 0 volt, for example. It is assumed, for example, that the levels on the first sense amplifier supply line 380 and on the second sense amplifier supply line 382 are steadily at 0 volt, for example, during the entire write cycle. In addition, levels at the outputs of the third bit line driver 372 and of the fourth bit line driver 373 may also be steadily at about 0 volt during the entire write cycle, for example. The word line 360 may be activated at a time t1, for example (e.g., by a sequential controller). At this point in time, a level of 0 volt may be present, for example, on the first bit line 310 and on the complementary first bit line 310b, as may be seen from the second graphic representation 394. In addition, the switch control signal 378 may still be inactive at the time t1, so that the switches 374 to 377 are still open. At a time t2, which follows the time t1, the switch control signal 378 (CSL) may be activated, for example, as may be seen from the fourth graphic representation 398. In this manner, the switches 374 to 377 are closed, and the levels present at the outputs of the bit line drivers 370 to 373 are driven to the bit lines or complementary bit lines 310, 310b, 312, 312b. Thus, for example, a level present on the first bit line 310, which is described by the curve characteristic 394c, rises to a value of, e.g., about 0.5 volt. By contrast, a level present on the complementary first bit line 310b remains at 0 volt, for example. Thus, the storage capacitor 320a of the first memory cell 320 is charged to the potential of the first bit line 310 via the switched-on n-channel MOS field-effect transistor 320b. The storage capacitor 322a of the second memory cell 320, however, is charged to the potential of the second bit line 312 via the closed MOS field-effect transistor 322b.

At a time t3, which follows the time t2, the word line 360 is set to an inactive state. Thus, the storage capacitor 320a is disconnected from the first bit line 310. Also, by deactivating the word line 360, the storage capacitor 322a of the second memory cell 320 is disconnected from the second bit line 312. Thus, the charge stored on the storage capacitors 320a, 322a is no longer influenced by the potentials of the bit lines 310, 312, apart from parasitic effects. In other words, the memory cells 320, 322 are in a memory state.

At a time t4, which follows the time t3, the switch control signal 378 (CSL) is deactivated again, for example. Thus, for example, the bit line drivers 370 to 373 are disconnected from the corresponding bit lines 310, 310b, 312, 312b. Thus, for example, the potential of the first bit line 310 goes down to 0, as is described by the curve characteristic 394c.

It may thus be summarized that FIG. 3a shows a block diagram with a connection for the primary sense amplifiers 340, 342 and the secondary sense amplifiers 370, 371, 372, 373. The potentials plotted in FIG. 3a describe, for example, writing a weak zero to the first memory cell 320 (cell 1) for the first bit line 310 (BL1). The other bit lines, for example, the complementary bit line or reference bit line 310b (bBL1) are all at 0 volt, for example. In addition, for example, the first sense amplifier supply line 380 (NCS) and the second sense amplifier supply line 382 (PCS) are also at 0 volt. Thus, for example, the n-channel MOS field-effect transistors (n FETs) of the bit line systems are switched off via the gate voltages or gate potentials. The p-channel MOS field-effect transistors (or p FETs) are further switched off, for example, via a source-drain voltage difference of 0 volt. In a write operation, for example during writing to the memory cells 320, 322, the switch control lines 378 (CSL) are set to 1.5 volts, for example, so that the bit lines 310, 310b, 312, 312b, for example, are written via the secondary sense amplifiers 370, 371, 372, 373 (SSA).

In one embodiment, the levels output by the secondary sense amplifiers 370, 371, 372, 373 are adjustable via data lines, for example. Thus, for example, those bit line drivers or those secondary sense amplifiers 370, 371, 372, 373 which are provided with a “0”, for example, in a test operation by data lines will drive a VBLL level, whereas the other bit line drivers or secondary sense amplifiers (i.e., for example, those secondary sense amplifiers 370, 371, 372, 373 provided with a “1” in the test operation) will drive a level of, e.g., 0 volt. A VBLL level here is understood to mean a bit line level, for example, which causes a weak “0” to be written to a corresponding memory cell. Further it is assumed that a level of 0 volt causes, for example, a strong “0” to be written to the corresponding memory cell. Other associations between levels and strong or weak logic values are possible.

A potential VBLH may also be set, for example, to a maximum value, so that a current-carrying p-channel MOS field-effect transistor or p FET, the source of which is connected to the first bit line 310 (BL1), is nearly switched off via a substrate controller. In other words, a corresponding substrate controller may achieve, for example, that the first p-channel MOS field-effect transistor 340c is nearly switched off despite the presence of a gate-source voltage of 0.5 volt.

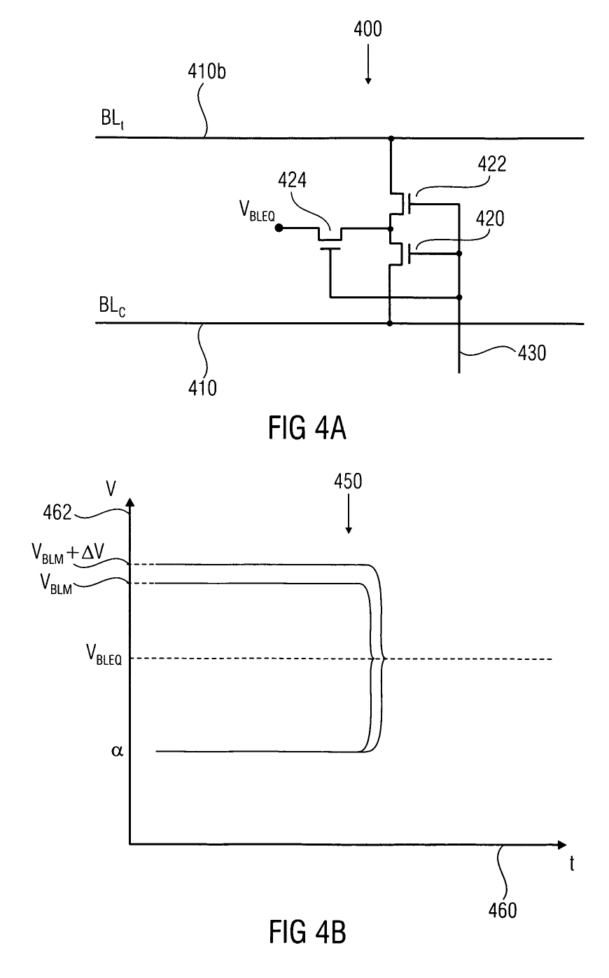

The architecture and mode of operation of an optional precharge circuit which may be employed, for example, in connection with the memory circuits 100, 200, 300, will be described below with reference to FIGS. 4a and 4b. The precharge circuit in accordance with FIG. 4a is designated by 400 in its entirety and may replace, for example, the precharge circuit 250, 252 of the circuitry 200. In addition, the precharge circuit 400 may also be added to the memory circuit 300 in accordance with FIG. 3a. With regard to the precharge circuit 400 it shall initially be noted that in one embodiment, the precharge circuit is coupled both to a bit line 410 (also referred to as BL_{c}) and to a complementary bit line 410b belonging thereto. The bit line 410 may correspond, for example, to the bit line 210 or to the bit line 310. In this case, for example, the complementary bit line 410b may correspond to the complementary first bit line 210b or to the complementary first bit line 310b. In a further embodiment, the bit line 410 may correspond, for example, to the second bit line 212 or to the second bit line 312. In this case, for example, the complementary bit line 410b may correspond to the complementary second bit line 212b or to the complementary second bit line 312b.

The precharge circuit 400 comprises, for example, a first switch 420, a second switch 422 and a third switch 424. This first switch 420, the second switch 422 and the third switch 424 may be formed, for example, by n FETs or n-channel MOS field-effect transistors in each case. For example, a first channel terminal of the first n-channel MOS field-effect transistor 420 may be coupled to the bit line 410. A first channel terminal of the second n-channel MOS field-effect transistor 422 may further be coupled to the second bit line 410b. A second channel terminal of the first n-channel MOS field-effect transistor 420 may further be coupled, for example, to a second channel terminal of the second n-channel MOS field-effect transistor 422. A node at which the second channel terminal of the first n-channel MOS field-effect transistor 420 is coupled to the second channel terminal of the second n-channel MOS field-effect transistor 422 may further be coupled to a first channel terminal of the third n-channel MOS field-effect transistor 424. A second channel terminal of the third n-channel MOS field-effect transistor 424 may further be coupled to a feed for a precharge potential V_{BLEQ}. Also, the gate terminals of the three n-channel MOS field-effect transistors 420, 422, 424 may be interconnected so as to receive a precharge control signal 430.

However, it shall be noted that the n-channel MOS field-effect transistors may be replaced by other elements acting as switches. For example, p-channel MOS field-effect transistors may readily be used. Quite generally, any field-effect transistors or bipolar transistors may be used.

With respect to the mode of operation of the precharge circuit 400 it may be established that when activating the precharge control signal 430, the first switch 420 and the second switch 422 are closed, so that the potentials present on the bit line 410 and on the bit line 410b complementary thereto may average each other out, for example, and form a mean value. Also, the third switch 424 is closed, so that the potentials of the bit line 410 and of the complementary bit line 410b are at least approximately set to the precharge potential V_{BLEQ}. Thus, in addition to the charge balancing between the bit line 410 and the complementary bit line 410b, which is effected via the first switch 420 and the second switch 422, the potential of the bit lines 410, 410b is set to a desired precharge value.

Respective time curves of the signals are shown in FIG. 4b, for example. FIG. 4b depicts a graphic representation of wave forms as may occur when employing the precharge circuit 400 in accordance with FIG. 4a. The graphic representation in accordance with FIG. 4b is designated by 450 in its entirety. The time is plotted on an abscissa 460, and a voltage level of the different signals is plotted on an ordinate 462. It shall be assumed below, for example, that the bit line 410 takes on a potential of, e.g., 0 volt (for example, in relation to the reference potential GND) prior to the performance of the pre-load operation (i.e., also prior to activation of the precharge signal 430). In addition, it is assumed that the complementary bit line 410b takes on a level V_{BLM} prior to activation of the precharge signal 430. In the first example it is assumed that a desired precharge potential V_{BLEQ} is halfway between the initial potential of the bit line 410 and the initial potential of the complementary bit line 410b, and that further the capacitance of the bit line 410 and the capacitance of the complementary bit line 410b are at least approximately equal in size. In this case, the potentials of the bit line 410 and of the complementary bit line 410b balance each other out in that the first switch 420 and the second switch 422 are closed, so that the potential V_{BLEQ} will be present on both bit lines 410, 410b after a sufficient amount of time has passed. In this case, the charge balance could also occur without closure of the third switch 424.

In a further example it is assumed that a level of 0 volt is present on the first bit line 410 prior to activation of the precharge control signal 430, whereas a level of V_{BLM}+ΔV is present on the complementary bit line 410b prior to activation of the precharge control signal 430. A mere charge balance between the bit line 410 and the complementary bit line 410b in this case results in a potential higher than the desired precharge potential V_{BLEQ}. By the additional closure of the third switch 424, in this case both the bit line 410 and the complementary bit line 410b are set to the desired precharge potential V_{BLEQ}, as may be seen from FIG. 4b.

One may thus summarize that the precharge circuit 400 may be employed, for example, to set a bit line and a complementary bit line belonging thereto to identical potentials (for example, in preparation for reading out a memory location). By contrast, however, a bit line and a bit line complementary thereto may be set to different potentials for writing a weak value to a memory cell, as was described above.

It shall also be noted that the bit line and the bit line complementary thereto are set, by the precharge circuit 500, to a potential which is essentially halfway between a first potential representing a strong “0”, and a second potential representing a strong “1”. For writing a weak “0” or a weak “1” to a memory cell, however, one uses such levels, or drives such levels to the bit lines, which differ from the precharge level V_{BLEQ} by at least 0.1 volt.

FIG. 5 shows a block diagram of a bit line driver for use in an inventive circuit in accordance with an embodiment of the invention. The bit line driver in accordance with FIG. 5 is designated by 500 in its entirety. The bit line driver 500 may thus replace, for example, the bit line driver 270 and/or the bit line driver 272 of the memory circuit 200. Likewise, the bit line driver 500 may replace, for example, the bit line drivers 370 to 373 of the memory circuit 300. For example, the bit line driver 500 comprises an input for a data signal 580 as well as an input for a mode signal 581. The data signal 580 may correspond to the data signal 280 or to the data signal 282, for example. The mode signal 581 may correspond to the mode signal 281, for example. The bit line driver further comprises an output 571 for a bit line driver output signal 584. Quite generally speaking, the bit line driver 500 is designed to create, on the basis of the data signal 580 and the mode signal 581, the bit line driver output signal 584 such that the bit line driver output signal 584 may take on at least three different signal values or signal levels, or is driven to at least three different signal levels, depending on the input signals. In one embodiment, this functionality may be achieved in that the bit line driver comprises a first two-levels driver 590 and a second two-levels driver 592. The first two-levels driver 590 comprises, for example, a p-channel MOS field-effect transistor 590a belonging to it and an n-channel MOS field-effect transistor 590b belonging to it. A drain-source path of the p-channel MOS field-effect transistor 590a of the first two-levels driver 590 is connected, for example, between the output 571 of the bit line driver 500 and a first supply potential V_{BLM}. A drain-source path of the n-channel MOS field-effect transistor 590b of the first two-levels driver 590 is further connected, for example, between the output 571 of the bit line driver 500 and the reference potential GND. Gate terminals of the p-channel MOS field-effect transistor 590a and of the n-channel MOS field-effect transistor 590b are separately controllable, for example, and are coupled, for example, to a logical block 594. The second two-levels driver 592 comprises, for example, a p-channel MOS field-effect transistor 592a which belongs to it and the drain-source path of which is connected, for example, between a second potential V_{BLL} and the output 571 of the bit line driver 500. In addition, the second two-levels driver 592 comprises, for example, an n-channel MOS field-effect transistor 592b which belongs to it and the drain-source path of which is connected between the output 571 of the bit line driver 500 and the reference potential GND. Gate terminals of the p-channel MOS field-effect transistor 592a and of the n-channel MOS field-effect transistor 592b are separately controllable, for example, and are coupled to the logical block 594.

In addition, it shall be noted that the potential V_{BLM} represents a strong “1”, for example. The potential V_{BLL}, however, represents a weak “0”, for example. The reference potential GND represents a strong “0”, for example.

For example, the logical block 594 may be designed to activate the p-channel MOS field-effect transistor 590a when the bit line driver output signal 584 is to be driven to a strong “1”. In this case, the remaining MOS field-effect transistors 590b, 592a, 592b are deactivated, for example. However, if the bit line driver output signal 584 is to be driven to a strong “0”, the logic 594 may control the MOS field-effect transistors 590a, 590b, 592a, 592b such that, for example, at least one of the n-channel MOS field-effect transistors 590b, 592b is conductive, whereas the two p-channel MOS field-effect transistors 590a, 592a are non-conductive. If, in addition, the bit line driver output signal 584 is to be driven to a weak “0”, the logical block 594 may control, for example, the MOS field-effect transistors 590a, 590b, 592a, 592b such that the p-channel MOS field-effect transistor 592a of the second two-levels driver 592 is conductive, whereas the remaining MOS field-effect transistors are non-conductive, for example.

It shall be noted that there are clearly different possibilities, however, of realizing the bit line driver which allow driving an output of the bit line driver to at least three different levels.

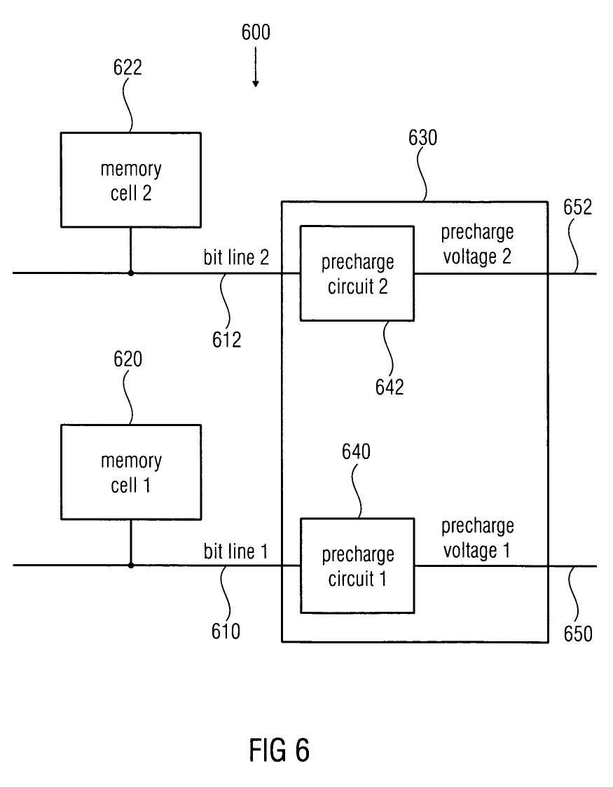

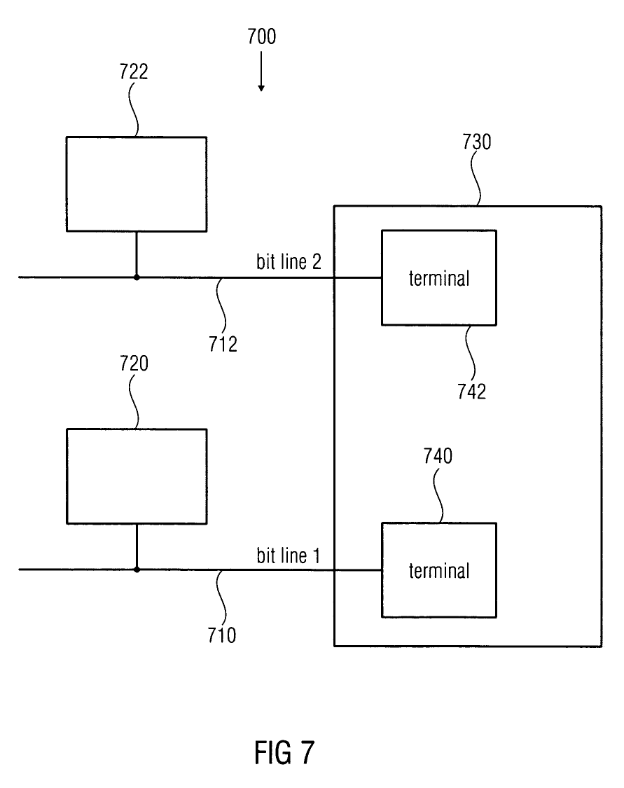

Further possibilities which enable bit line-selective writing of a weak value to a memory cell coupled to a selected bit line will be described below with reference to FIGS. 6 and 7.

FIG. 6 shows a block diagram of a memory circuit in accordance with an embodiment. The memory circuit in accordance with FIG. 6 is designated by 600 in its entirety. The memory circuit 600 comprises a first bit line 610 and a second bit line 612. A first memory cell 620 is coupled (or couplable, via a switch) to the first bit line 610, and a second memory cell 622 is coupled (or couplable, via a switch) to the second bit line 612.

The memory circuit 600 further comprises a bit line control circuit 630 coupled to the first bit line 610 and the second bit line 612. The bit line control circuit 630 comprises, for example, a first precharge circuit 640 designed to receive a first precharge voltage 650 and to precharge the first bit line 610 as a function of the first precharge voltage 650. The bit line control circuit 630 further comprises a second precharge circuit 642 coupled to the second bit line 612 and further designed to receive a second precharge voltage 652. The second precharge circuit 642 is designed to precharge the second bit line 612 as a function of the second precharge voltage 652.

The bit line control circuit 630 is configured, for example, such that the two precharge circuits 640, 642 may have different precharge voltages 650, 652 applied thereto. For example, one of the precharge voltages 650, 652 may be selected such that one of the bit lines 610, 612 may be set, by the corresponding precharge circuit 640, 642, to a state which allows writing a weak value to a corresponding memory cell 620, 622. For example, the first precharge voltage 650 may be selected such that the first bit line 610 is precharged to a weak write potential by the first precharge circuit 640. This weak write potential may then be used to write a weak value to the first memory cell 620. In the same write operation, one may achieve, by a suitably selected second precharge voltage 652, that the second precharge circuit 642 precharges the second bit line 612 to a strong write level, so that a strong value (e.g., a strong “0” or a strong “1”) may be written to the second memory cell 622.

For example, the precharge circuit 640, 642 may have a structure as was described with reference to FIG. 4a. However, the precharge circuits 640, 642 may also be designed differently. For example, the precharge circuits 640, 642 may be designed to enable pre-charging the bit lines 610, 612 to different precharge voltages, one of the precharge voltages, for example, being selected such that same enables writing of a weak value to a memory cell.

A further circuitry enabling bit line-selective writing of a weak value to a memory cell shall be described below. FIG. 7 shows a block diagram of a memory circuit in accordance with a further embodiment. The memory circuit in accordance with FIG. 7 is designated by 700 in its entirety. The memory circuit 700 comprises a first bit line 710 and a second bit line 712. The memory circuit 700 further comprises a first memory cell 720 coupled or couplable to the first bit line 710 via a switch. The memory circuit 700 further comprises a second memory cell 722 coupled or couplable to the second bit line 712 by a switch. The memory circuit 700 further comprises a bit line control circuit 730 designed to write, in a bit line-selective manner, a weak value to a memory cell coupled to a selected bit line. In one embodiment, the bit line control circuit may comprise, inter alia, a first terminal 740 coupled, for example, to the first bit line 710. The bit line control circuit 700 may further comprise a second terminal 742 coupled, for example, to the second bit line 712. The terminals 740, 742 may be test pads or contact areas, for example, which may be contacted from outside so as to apply different voltages to the bit line 710, 712. Such an arrangement allows, for example, putting different bit lines to levels which may be set from outside. Thus, a level which enables writing a weak “0” or a weak “1” may be set.

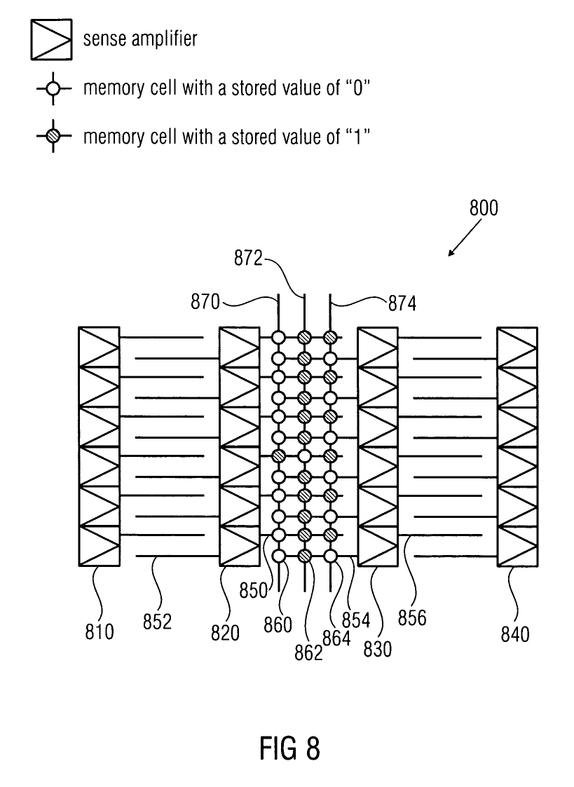

Situations or configurations wherein the writing of a weak value may be employed, for example, to simplify a test of a memory circuit or a chip test will be shown below with reference to FIGS. 8 to 10. FIG. 8 shows a block diagram or a section of a block diagram of a memory circuit in accordance with an embodiment of the invention. The memory circuit in accordance with FIG. 8 is designated by 800 in its entirety. The memory circuit 800 comprises a first strip 810 of sense amplifiers, a second strip 820 of sense amplifiers, a third strip 830 of sense amplifiers, and a fourth strip 840 of sense amplifiers. A strip of sense amplifiers comprises a plurality of sense amplifiers located adjacent to one another essentially along a line. Each of the sense amplifiers shown of the second strip 820 of sense amplifiers as well as of the third strip 830 of sense amplifiers is coupled to two bit lines in each case, namely to a bit line or target bit line, and to a complementary bit line or reference bit line. A bit line or target bit line is designated by 850 by way of example, and a corresponding associated complementary bit line or reference bit line is designated by 852, for example. As was described above, the bit lines 850 and the complementary bit line 852 belonging to same are both coupled to the same sense amplifier. A second bit line or target bit line is designated by 854, and a complementary bit line belonging to it is designated by 856. The bit lines or target bit lines 850, 854 coupled to adjacent sense amplifier strips 820, 830 may be arranged, for example, in an intermeshing manner as may be seen, for example, from FIG. 8. The target bit lines 850, 854 may further be coupled to associated memory cells, some of which are designated, by way of example, by 860, 862, 864. Memory cells having a value of “0” stored therein are marked by an empty circle, whereas memory cells having a value of “1” stored therein are depicted by a filled-in circle.

The target bit lines 850, 854 are coupled or may be coupled to the memory cells via corresponding switches. The switches mentioned may be closed, for example, by activation of a corresponding word line. Some word lines which are drawn in by way of example are designated by 870, 872 and 874. Also, it shall be noted that memory cells coupled to the first word line 870 mainly (with one exception) have a value of “0” stored therein. Thus, the word line 870 may be considered, for example, a first word line having a majority of “0”. Memory cells coupled to the second word line 872 mainly (with one exception) have the value of “1” stored therein. Thus, the second word line 872 may be considered a word line having the majority of “1”. Memory cells coupled to the third word line 874 have the value of “0” stored therein about as many times as the value of “1”. Thus, the third word line 874 may be considered a word line having mixed charges.

As was already mentioned above, the bit line 856 is a reference bit line belonging to the bit line 854.

It may thus be established, all in all, that FIG. 8 shows a block diagram of a memory cell field having an open bit line architecture. Three word lines having majority charges of “1” and “0” or having mixed charges may be seen from FIG. 8.

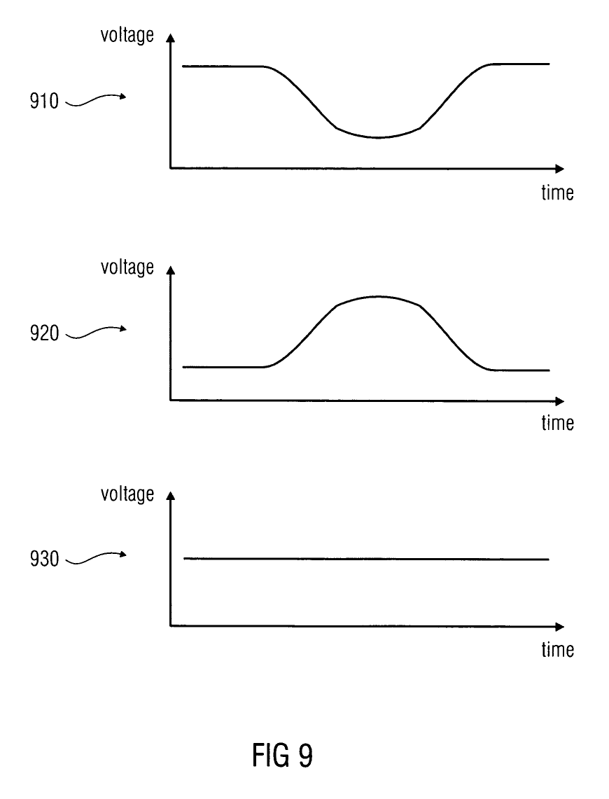

In other words, the block diagram in accordance with FIG. 8 shows a section of a memory cell field in an open bit line architecture. Bit line branches, one of each individual sense amplifier, extend in different directions (see the bit line 854 and the reference bit line 856 belonging to it). If, for example, the first word line 870 having a majority charge of “0” in the cells is opened, all bit lines in an area between the second strip 820 of sense amplifiers and the third strip 830 of sense amplifiers will be developed, for example, from a precharge voltage or from a precharge potential V_{BLEQ} toward a reference potential GND. In other words, the bit lines located between the second strip 820 of sense amplifiers and the third strip 830 of sense amplifiers will be recharged from the precharge potential V_{BLEQ} to the reference potential GND. All networks, or at least some networks, coupled to the bit lines mentioned by parasitic capacitances, or connected to the bit lines by parasitic capacitances, will experience a voltage dip, as is shown in a first graphic representation 910 of FIG. 9. It can be shown that a read operation for an individual cell having an inverse minority carrier charge may be negatively affected by this voltage dip. For example, a read-out operation of the individual memory cell marked in black, coupled to the first word line 870 and having a value of “1” stored therein may be impaired by read-out of the remaining memory cells which are coupled to the first word line 870 and have the value of “0” stored therein.

This also applies in the case of a complete inversion. For example, the second word line 872 (or the memory cells coupled to the second word line 872) has (have) a majority carrier charge of “1” and an individual memory cell with a stored “0”.

An amplification operation of all bit lines (apart from one, for example) from the precharge value, for example, from V_{BLEQ}, to V_{BLH} results, for example, in a voltage bump in an area between the second sense amplifier strip 820 and the third sense amplifier 830, which voltage bump may negatively affect the read operation of the individual “0”.

Accessing the third word line 874 with, for example, 50% “1” and “0” topologies, respectively (or with 50% stored “1” values and 50% stored “0” values) leads to a balanced situation. Half of all of the bit lines, for example, perform an upward-coupling operation on networks which are coupled in a parasitically capacitive manner, and the other perform a downward-coupling operation on them, so that the sum of all of the coupling contributions averages straight out to zero.

This means that in the case of a majority charge present along a word line a negative influence on the amplification operation results for the minority charges by means of coupling. This is essentially a delay in the read behavior.

For example, in order to obtain a reliable test, it is because of this behavior that in some testing methods all cells may be tested with an inverse background in each case, which in some cases leads to an extreme increase in the test duration.

A brief explanation will once again be given below of the voltage response upon activation of different word lines. In this context, FIG. 9 shows a graphic representation of time curves of a voltage level for three different cases. In other words, FIG. 9 shows three voltage-time diagrams which describe signal levels upon activation of the word lines 870, 872, 874 in accordance with FIG. 8 and upon simultaneous starting of the amplification operation. For example, if the first word line 870 is activated for a read-out, the bit lines belonging to it (i.e., inter alia, the bit lines 850, 854) are recharged from a precharge level to a level which corresponds to a stored “0”. Since, for example, all bit lines will be recharged, for example, to a lower value in terms of potential essentially at the same time, a capacitive coupling will give rise to a voltage dip on other lines capacitively coupled to the bit lines. This voltage dip is shown in the first schematic representation 910. If, however, the second word line 872 is activated, almost all of the bit lines coupled to the second word line 872 are simultaneously recharged to a value corresponding to a stored “1”. Thus, a voltage level on other lines capacitively coupled to the bit lines mentioned is temporarily raised, as is shown in a second graphic representation 920. If, in addition, the third word line 874 is activated, a capacitive influence exerted on other lines on account of recharging the bit lines is small, since the memory cells coupled to the third word line 874 have both values of “0” and values of “1” stored therein in almost equal numbers.

The corresponding small influence exerted on other signals is shown in a third graphic representation 930.

In one embodiment, a signal tolerance may be checked (for example, when testing a memory circuit). For example, a signal tolerance of a weak zero in a background of strong zeros may be checked. The expressions “weak” and “strong” may refer, for example, to a voltage level within a memory cell. With reference to, for example, a reference potential GND, a voltage level of 0 volt may be regarded as a strong voltage level describing a strong zero, for example. Values of between 0 volt and an equalize voltage or precharge voltage V_{BLEQ} may be regarded as weak zeros, for example.

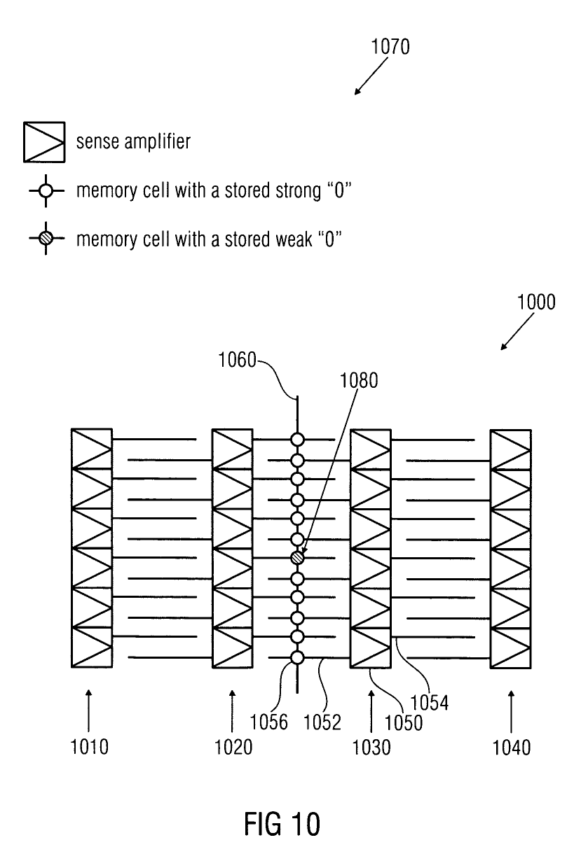

FIG. 10 shows such a case where strong and weak values (here: strong and weak zeros) are stored within a memory circuit. FIG. 10 shows a block diagram of a memory cell field having an open bit line architecture. The block diagram in accordance with FIG. 10 is designated by 1000 in its entirety. The memory cell field 1000 comprises, for example, a first sense amplifier strip 1010, a second sense amplifier strip 1020, a third sense amplifier strip 1030, and a fourth sense amplifier strip 1040. One sense amplifier 1050, for example, has a bit line 1052 associated with it as well as a reference bit line 1054 belonging to same. The bit line 1052 is coupled to a memory cell 1056, for example, or may be coupled to it via a switch which can be closed by activation of a word line 1060. In this context it shall be noted that the memory cell 1056, which is shown by a symbol indicated in a legend 1070, may correspond to the above-described memory cell 120, 122, 220, 222, 320, 322. For example, eleven memory cells having a strong “0” stored therein are coupled to the word line 1060. The memory cells comprising the stored strong “0” are shown by the corresponding symbol indicated in the legend 1070. In addition, a memory cell 1080 having a weak “0” stored therein is coupled to the word line 1060. The word line 1060 may thus be considered a word line with a majority of “0”. Thus, one may summarize that FIG. 10 shows a case where both strong zeros and weak zeros are stored in different memory cells (for example, in memory cells 1056, 1080) which are coupled to a word line 1060. In the event of an activation (i.e., for example, in the event of an activation of the word line 1060), the voltages of the cell capacitances, i.e., for example, the majority zeros, will balance themselves out with the precharge voltage or V_{BLEQ} voltage of the bit lines connected. This is a charge balancing, wherein, for example, the voltages in all cell capacitances increase. In this context, for example, a plate voltage VPL connected to a different electrode of all cells is pulled upwards in terms of capacitance. The weak “0” (i.e., for example, a potential at a bit line terminal of a memory cell which has a weak “0” stored therein) may be pulled across a threshold in terms of capacitance, for example, as of which threshold the (associated) sense amplifier amplifies, or recognizes, a “1”. A signal tolerance, i.e., a voltage level in a cell having a weak “0”, is to be adjusted in a test, for example. It may be desirable, for example, to adjust a memory cell to a specific signal level which corresponds to a weak zero, for example. In this case one may test, for example, whether the weak “0” stored in the memory cell mentioned may still be read out correctly. In addition, the voltage stored in a memory cell may be varied in a controlled manner, for example, in subsequent test phases, and one may verify at which level values a value content of a memory cell can still be read out correctly.

Testing a memory cell is facilitated, for example, in that a level desired (for example, a voltage level desired) may directly be written to a memory cell. For example, by writing a weak value in a bit line-selective manner, the situation described using FIG. 10 may be created wherein a word line (for example, the word line 1060) comprises majority charges of “0” (for example, strong values of “0”) and a weak “0”.

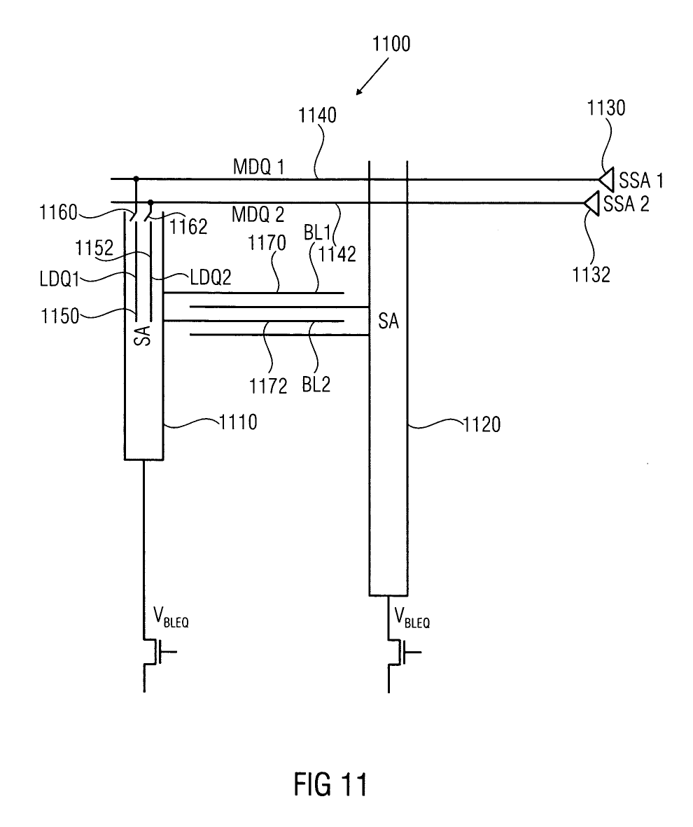

FIG. 11 shows a block diagram of a memory circuit in accordance with an embodiment of the invention. The memory circuit in accordance with FIG. 11 is designated by 1100 in its entirety. The memory circuit 1100 comprises a first sense amplifier strip 1110 as well as a second sense amplifier strip 1120. The memory circuit 1100 further comprises a first secondary sense amplifier 1130 as well as a second secondary sense amplifier 1132. The first secondary sense amplifier 1130 is also designated by SSA1, and the second secondary sense amplifier 1132 is also designated by SSA2. The memory circuit 1100 further comprises a first main data line 1140 (also designated by MDQ 1) as well as a second main data line 1142 (also designated by MDQ 2). The first main data line 1140 is coupled, for example, to an output of the first secondary sense amplifier 1130, and the second main data line 1142 is coupled, for example, to the output of the second secondary sense amplifier 1132. The first sense amplifier strip 1110 further comprises, for example, a first side data line, or subsidiary data line, or branching, data line, 1150 (also designated by LDQ1) as well as a second side data line 1152 (also designated by LDQ2). The first side data line 1150 is coupled to the first main data line 1140 via a switch 1160. Thus, the first side data line 1150 may be coupled, in an electrically effective manner, to the first main data line 1140 and, thus, to the output of the first secondary sense amplifier 1130, for example, by closure of the switch 1160. The second side data line 1152 may be coupled to the second main data line 1142 and, thus, to the output of the second secondary sense amplifier 1132, for example, by a switch 1162. Within a sense amplifier of the sense amplifier row 1110, for example the first side data line 1150 or the second side data line 1152 may be coupled to a bit line, as was described, for example, with reference to FIG. 3a. In other words, the first side data line 1150 (LDQ 1) may correspond, for example, to the line designated by LDQ1 in FIG. 3a. The second side data line 1152 (LDQ 2) may correspond, for example, to the line designated by LDQ2 in FIG. 3a.

The circuitry 1100 further comprises, for example, a first bit line 1170 (BL1) as well as a second bit line 1172 (BL2). The first bit line 1170 (BL1) may correspond, for example, to the first bit line 310 shown in FIG. 3a. The second bit line 1172 (BL2) may correspond, for example, to the second bit line 312 shown in FIG. 3a.

The secondary sense amplifiers 1130, 1132 may each be coupled to several sense amplifier strips. For example, the first main data line 1140 may be connected to an side data line (LDQ1) of a third sense amplifier strip (not shown in FIG. 11). Likewise, for example, the second main data line 1142 may be coupled to an side data line (LDQ2) of the third sense amplifier strip via a corresponding switch. One may thus establish, all in all, that a secondary sense amplifier 1130, 1132 may serve to control several sense amplifier strips. Thus, an output of the secondary sense amplifier 1130, 1132 may be coupled to more than one bit line by a switch or a series of switches, so as to provide, as a function of which switch(es) is (are) closed, for example, a read-out bit line with a level corresponding to a weak value.

The memory circuit 1100 in accordance with FIG. 11 further comprises a means for providing a precharge voltage V_{BLEQ} for the sense amplifier strips. For this purpose, a circuitry may be provided, for example, which is configured to couple two or more sense amplifier strips 1110, 1120 (or, in some embodiments, even all of the sense amplifier strips) to the same precharge potential V_{BLEQ}, or to apply the same precharge potential V_{BLEQ} to same. Thus, all bit lines may be precharged to the precharge potential V_{BLEQ} in a precharge operation, for example.

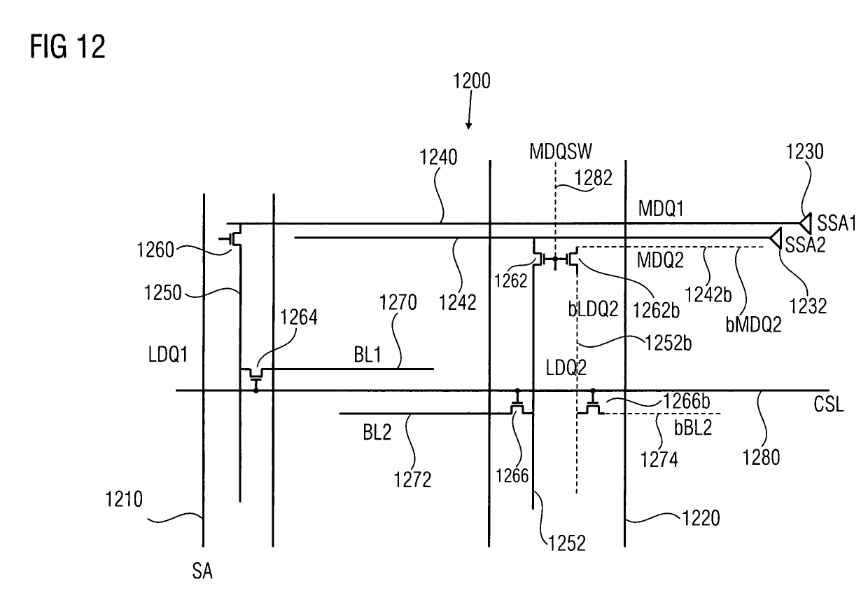

FIG. 12 shows a block diagram of a memory circuit in accordance with an embodiment of the present invention. The memory circuit in accordance with FIG. 12 is designated by 1200 in its entirety. The memory circuit 1200 comprises, for example, a first sense amplifier strip 1210 as well as a second sense amplifier strip 1220. The memory circuit 1200 further comprises a first secondary sense amplifier 1230 (SSA1) as well as a second secondary sense amplifier 1232 (SSA2). A data signal is present at the output of the first secondary sense amplifier 1232, the signal being supplied to a first main data line 1240 (MDQ1). Also, a further data signal is present at the output of the second secondary sense amplifier 1232, the further data signal being supplied to a second main data line 1242 (MDQ2). The first sense amplifier strip 1210 comprises, for example, a first side data line 1250 coupled to the first main data line 1240 via a corresponding associated switch 1260. The first side data line 1250 is also designated by LDQ 1. The second sense amplifier strip 1220 comprises a second side data line 1252 coupled to the second main data line 1242 via a corresponding switch 1262. The first side data line is coupled to a first bit line 1270 (BL1) via a switch 1264. The second side data line 1252 is coupled to a second bit line 1272 (BL2) via a corresponding switch 1262.

The switch 1264, via which the first bit line 1270 is coupled to the first side data line 1250, as well as the switch 1266, via which the second bit line 1272 is coupled to the second side data line 1252, are controlled, for example, via a common switch control signal 1280 (CSL). The switch 1262 coupling the second main data line 1242 to the second side data line 1252 is controlled via a select signal 1282 (MDQSW). Thus, it may be seen from FIG. 12 that, for example, the first data signal provided by the first secondary sense amplifier 1230 may be supplied to a sense amplifier strip (specifically, to the first sense amplifier strip 1210) different from the one to which the second data signal provided by the second secondary sense amplifier 1232 may be supplied. Also, it may be seen that the first bit line 1270 and the second bit line 1272, which may be simultaneously coupled to the associated side data lines 1250, 1252, for example, may still have different data signals applied to them.

In addition, there may (optionally) be a symmetrical architecture wherein, for example, a data line (or each data line) has a complementary data line associated with it. For example, a complementary second data line 1274 (bBL2) belonging to the second data line 1272 is shown in FIG. 12. The complementary second data line 1274 may be controlled, for example, by a complementary second data signal. For this purpose, a complementary main data line 1242b (bMDQ2) may exist, for example, which is connected to the output of a complementary second secondary sense amplifier (not shown here), for example. The complementary second main data line may be coupled to a complementary second side data line 1252b via a corresponding switch 1262b, for example. The complementary second side data line 1252b may be coupled, for example, to the complementary second bit line 1274 via an associated switch 1266b. Both the switches 1266 and 1266b, which couple the second bit line 1272 and the complementary second bit line 1274 to the corresponding side data lines 1252, 1252b, may be controlled by the common switch control signal 1280 (CSL). In addition, the switches 1262, 1262b, which couple the second side data line 1252 and the complementary second side data line 1252b to the corresponding main data lines, may also be controlled using the same control signal 1282 (MDQSW), as may be seen from FIG. 12.

It shall explicitly be pointed out that the architecture in accordance with FIGS. 11 and 12 is to be regarded as exemplary. There are indeed many different possibilities of coupling, e.g., the secondary sense amplifiers shown to the corresponding bit lines. In this context, the coupling may be effected, for example, in a switchable manner via one or several switches interconnected. But it is also possible to provide a secondary sense amplifier for each bit line. The distribution and the geometric arrangement of the sense amplifiers and of the bit lines may be varied in manifold respects. In addition, there are further possibilities of modification with regard to the complementary bit line. In some embodiments, control of the complementary bit line may be dispensed with. Rather, the complementary bit line may be employed as a reference bit line only, for example. For example, a complementary bit line or reference bit line need not be coupled to a secondary sense amplifier.

It shall also be noted that the architectures in accordance with FIGS. 11 and 12 may be employed, for example, in connection with the circuitries described using FIGS. 1, 2 and 3a. In this case, signals bearing identical designations are identical. Also, in this case the secondary sense amplifiers correspond to, or are identical to, the bit line drivers.

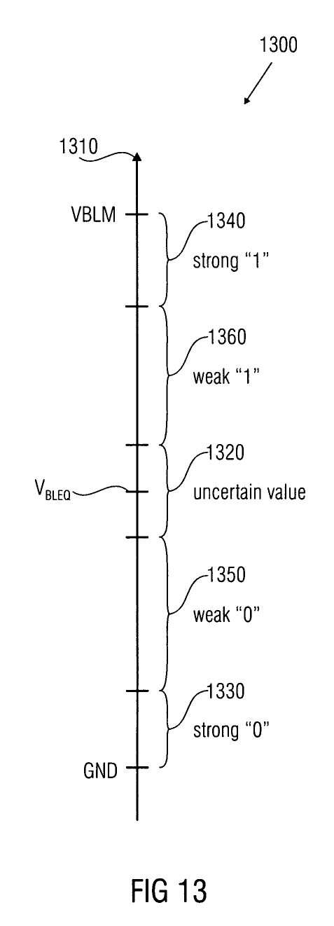

FIG. 13 shows a graphic representation of different levels as may occur in a memory cell or on a bit line. The graphic representation in accordance with FIG. 13 is designated by 1300 in its entirety. Different voltage ranges or level ranges or potential ranges are plotted along an axis 1310. For example, a reference potential GND is plotted on the axis 1310. Also, a maximum bit line level VBLM is plotted on the axis 1310. Furthermore, a precharge level V_{BLEQ} is plotted to which a bit line may be precharged by the precharge circuit 250, 252, 400, for example. For example, the precharge level VBLEQ at least approximately corresponds (for example, with a deviation of 100 mV at the most or 50 mV at the most) to a decision threshold of a primary sense amplifier. An interval around the precharge level VBLEQ forms a level interval, for example, which represents an uncertain value. In other words, if the bit-line side terminal of a storage capacitor of a memory source is at a potential within a so-called “uncertain-value interval” 1320 around the precharge level VBLEQ, the value stored in the memory cell may be read out only with a low level of reliability. The uncertain-value interval 1320 may form an interval of ±20 mV, for example, around the precharge level. However, the uncertain-value interval 1320 may also be larger and comprise, for example, a level range of ±100 mV around the precharge potential VBLEQ.

In addition, a level interval 1330 exists, for example, which is also referred to as a strong-“0” interval. The strong-“0” interval 1330 may comprise an interval of about 100 mV, for example, which comprises the reference potential GND, for example, or which is limited by the reference potential GND, for example. However, the strong-“0” interval may also be narrower or wider and may comprise a width of from 20 mV to 200 mV, for example.

Also, a level interval 1340 exists, for example, which is also referred to as a strong-“1” interval. The strong-“1” interval 1340 may comprise a width of about 100 mV, for example, and may comprise the maximum bit line potential VBLM, for example. In addition, the strong-“1” potential may alternatively be limited by the maximum bit line level VBLM. Also, the width of the strong-” 1” interval may vary between 20 mV and 200 mV, for example.

In addition, a level interval 1350 exists, also referred to as a weak-“0” interval. The weak-“0” interval 1350 lies between the strong-“0” interval 1330 and the uncertain-value interval 1320, for example. With regard to the level at the bit line terminal of a memory cell, or with regard to the level on a bit line, a weak-“1” interval 1360 also exists which lies between the uncertain-value interval 1320 and the strong-“1” interval 1340, for example.

One may thus establish, quite generally, that when writing a strong “0” to a memory cell, a level or potential within the strong-“0” interval 1330 is applied to the memory cell. In other words, when writing a strong “0”, an associated bit line is driven to a level within the strong-“0” interval, for example. However, when writing a weak “0”, the bit line is written to a level within the weak-“0” interval 1350. When pre-charging a bit line, bit lines may be precharged to the potential VBLEQ, for example, so that the potential of the precharged bit line lies within the uncertain-value interval 1320, for example. When writing a weak “1” to a memory cell, a write potential lying within the weak-“1” interval 1360 is applied, for example, to the memory cell to be written to. When writing a strong “1” to a memory cell, a level or potential lying within the strong-“1” interval 1340 is applied to the memory cell, for example.

One may thus summarize that a “weak value” within a memory cell comprises, for example, a weak “0” or a weak “1”. Writing a weak value to a memory cell therefore comprises writing a weak “0” or a weak “1”, for example, i.e., for example, applying a write potential which lies within the weak-“0” interval or within the weak-“1” interval to the memory cell.

In other words, a weak value, for example, is a value (for example, a voltage value or a potential value) which is closer to a decision threshold (for example, a decision threshold between a “0” value and a “1” value) than a corresponding strong value.

In some embodiments, in one operating state, writing a strong value (for example, writing a strong “0” or a strong “1”) to a memory cell is possible, whereas in another operating state, writing a weak value (for example, a weak “0” or a weak “I”)is possible. In other words, in some embodiments there are two possibilities of writing a “0” to a memory cell which differ with regard to the write level. By analogy therewith, in some embodiments there are two possibilities of writing a “1” to a memory cell which differ with regard to the write level.

It shall therefore be noted that, for example, in a normal operating state, wherein a memory circuit serves to store data, strong values are typically written to the memory cells. However, in a test operating state, in some embodiments, one or several weak values are written to one or several memory cells.

A strong write potential or a strong write level is understood to mean, for example, a write potential lying within the strong-“0” interval or within the strong-“1” interval, depending on whether a “0” or a “1” is to be written. A weak write potential or a weak write level, however, is understood to mean a potential lying within the weak-“0” interval 1350 or within the weak-“1” interval 1360, depending on whether a “0” or a “1” is to be written.

With regard to the graphic representation in accordance with FIG. 13 it shall be noted that a different association of the potentials with the values “0” and “1” may also be used, of course. For example, the value “1” may be represented by a low potential, whereas the value “0” may be represented by a higher potential. In this case, an interval representing a weak “0” will lie between the interval representing a strong “0” and the interval representing the uncertain value. Similarly, in this case, too, an interval representing the weak “1” will lie between the interval representing the strong “1” and the interval representing an uncertain value.

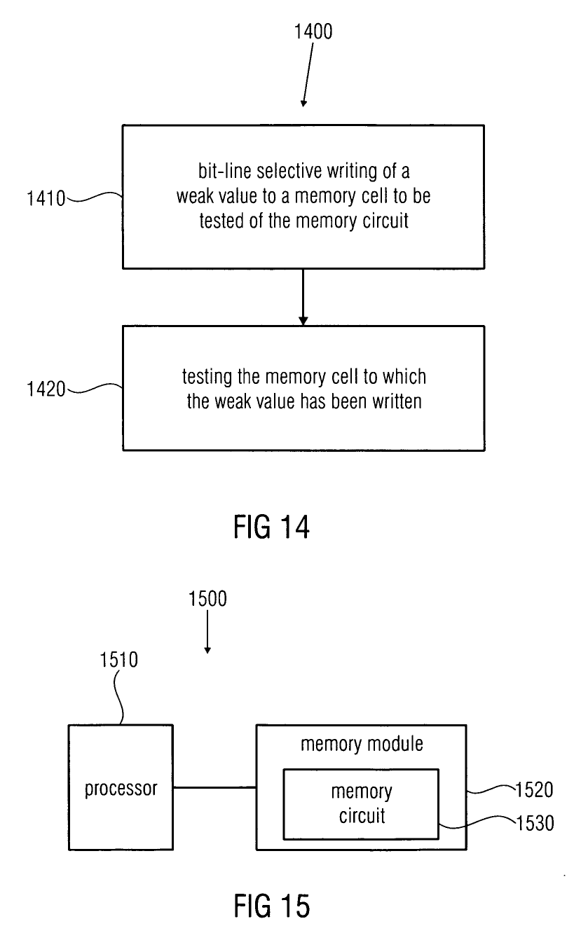

FIG. 14 shows a block diagram of a method of testing a memory circuit in accordance with an embodiment of the invention. The method in accordance with FIG. 14 is designated by 1400 in its entirety. In a first step 1410, the method 1400 comprises bit line-selective writing of a weak value to a memory cell to be tested of the memory circuit. The method 1400 further comprises, in a second step 1420, testing the memory cell to which the weak value has been written.

Testing the memory cell to which the weak value has been written may comprise, for example, verifying whether the value written to the memory cell may be read out in an error-free manner. However, testing the memory cell to which the weak value has been written may also comprise any other known and future concepts of testing a memory cell.

The method 1400 in accordance with FIG. 14 may further be extended by all of those steps or features which, in the context of the present description, have also been described with regard to the devices. For example, bit line-selective writing 1410 of a weak value to a memory cell to be tested may be effected as was explained in detail with reference to FIGS. 1 to 13.

The method 1400 may also be employed, for example, in connection with the devices described in the context of the present description. However, the method 1400 is not limited to such devices but may be generally employed in any devices suited to perform the method.

FIG. 15 shows a block diagram of a data processing system in accordance with an embodiment of the invention. The data processing system in accordance with FIG. 15 is designated by 1500 in its entirety. The data processing system 1500 comprises a processor 1510 and a memory module 1520. The memory module 1520 may be, for example, a static random access memory or a dynamic random access memory (DRAM). The memory module 1520 comprises a memory circuit 1530, which may be, for example, a memory circuit 100 in accordance with FIG. 1, a memory circuit 200 in accordance with FIG. 2a, or a memory circuit 300 in accordance with FIG. 3.

The processor 1510 is coupled to the memory module 1520 so as to read out data from the memory module or to write data to the memory module. Storage of data in this case is effected within the memory circuit 1530, for example.

One may summarize that some embodiments of the present invention enable efficient and fast writing of a selectable value to a memory cell in that, for example, a different VBLL value (which differs, for example, from a value representing a strong “0” or a strong “1”) is written to a bit line via a secondary sense amplifier. VBLL designates a low bit line value. In this context, the configuration of the primary sense amplifier may be used, as is shown in FIG. 3A.

In other words, in some embodiments of the invention, adaptation of the primary sense amplifier (or at least of the structure of the primary sense amplifier) may be used to enable the writing, for example, of a weak “0” or a weak “1” to a memory cell.

In some embodiments, a bit line pair (for example, consisting of a sacrifice bit line and a reference bit line) may be simultaneously connected to an LDQ/MDQ system using CSL switches (for example using the switches 374 to 377 in accordance with FIG. 3a or using the switches 1264, 1266, 1266b in accordance with FIG. 12). In some embodiments a test circuit may provide for a defined VBLL value (i.e., for example, a defined low value of the bit line) to be jointly written to the bit line system.

In some embodiments of the invention, a separate VBLL voltage source may be used, for example, which is written to the bit line system in a test operation, for example, via a secondary sense amplifier (or bit line driver).

A weak write level (or a weak write potential) which is written to a memory cell in a test operating state, for example, so as to represent a weak “0” or a weak “1” may be provided in manifold manners. For example, the corresponding voltage level VBLL may be provided by an external terminal of the memory circuit. Thus, for example, the voltage level VBLL may be predefined externally for a test of a chip comprising the memory circuit. For example, a pin or a pad may be provided so as to supply the corresponding voltage level VBLL, which represents a weak “0” or a weak “1”, to the memory circuit realized on a chip.

The voltage level representing a weak “0” or a weak “1”, however, may also be provided internally within the memory circuit. The corresponding voltage level may be derived from a supply voltage of the memory circuit via a voltage divider. However, other circuits may also be employed for providing a voltage level, such as a bandgap voltage source, for example. Operation-amplifier circuits may also be employed to provide a voltage level representing a weak “0” or a weak “1”.

One may establish that the concept explained in the context of the present description may be employed in a large number of circuits. For example, the above-described circuitry may be employed in dynamic random access memories, also known as DRAMs. The concept described, or the circuits and methods described, however, may also be implemented, for example, in connection with a processor or microcontroller having a memory belonging to it. The described circuit concept of applying, in a bit line-selective manner, a weak level or a weak value to a bit line connected to a memory cell may also be employed in connection with static memories (e.g., static random access memories, or static RAMs). In addition, the above-described concept may also be employed in connection with video memories or video processors having integrated memories.

Of course, the above-described circuits may be clearly modified without deviating from the concept described here. For example, the switches may be realized in any technology. In the context of the underlying concept, the details regarding the configuration of the primary or secondary sense amplifiers or bit line drivers are not important. The above-described circuits are therefore to be regarded as exemplary possibilities of realization.

The above-described write-in of a weak “0” may also be replaced by write-in of a weak “1”.

In addition, there are various possibilities of putting the circuit into the above-described test mode wherein a weak value may be written to a memory cell. For example, the test mode may be initiated by a command which is envisaged for this purpose and is given to the memory circuit via an interface. Alternatively or additionally, an external terminal may be provided, for example, via which the memory circuit may be put into the test mode. The external terminal may be a pin or a pad, for example.

In one embodiment, the above-described memory circuit may be monolithically integrated on a chip, so that both the memory cells and the bit lines belonging to them and the bit line drivers belonging to them are monolithically integrated on a chip. Such a monolithic integration is not absolutely mandatory, however.

One may thus summarize that, in one embodiment of the invention, testing the memory circuit may be substantially simplified and/or accelerated. While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

What is claimed is:

1. A memory circuit comprising:
a plurality of bit lines;
a plurality of memory cells writable via a respective bit line; and
a bit line control circuit,
the bit line control circuit being configured to write, in a bit line-selective manner, a weak value to a memory cell coupled to a bit line selected.

2. The memory circuit as claimed in claim 1, wherein the bit line control circuit is adapted to apply a weak write level at least to one selectively selectable bit line so as to write, in a bit line-selective manner, a weak value to a memory cell coupled to the bit line selected.

3. The memory circuit as claimed in claim 1, wherein the bit line control circuit comprises a bit line driver adapted to drive, in a bit line-selective manner, a bit line to three different voltage levels as a function of at least one control signal.

4. The memory circuit as claimed in claim 1, wherein the bit line control circuit is adapted to generate or cause, in a bit line-selective manner, in a first operating state, when writing to a memory cell to be written to, a first strong write level or a second strong write level on a bit line to which the memory cell to be written to is coupled, as a function of a memory value to be written to the memory cell to be written to, and
the bit line control circuit being adapted to generate or cause, in a bit line-selective manner, in a second operating state, when writing to a memory cell to be written to, optionally a strong write level or a weak write level on a bit line to which the memory cell to be written to is coupled.

5. The memory circuit as claimed in claim 4, wherein the first operating state is a normal operating state for reliably storing data, and wherein the second operating state is a test operating state for testing the memory circuit.

6. The memory circuit as claimed in claim 1, wherein the bit line control circuit is adapted to drive two bit lines associated with a same primary sense amplifier to two different levels during bit line-selective writing of a weak value, at least one of the two different levels being a weak write level.

7. The memory circuit as claimed in claim 1, the memory circuit comprising a primary sense amplifier adapted to amplify a potential difference existing between two bit lines coupled to the primary sense amplifier.

8. The memory circuit as claimed in claim 7, wherein the bit line control circuit is adapted to put the primary sense amplifier into an inactive state during writing of a weak value to a memory cell, the primary sense amplifier being associated with a bit line coupled to the memory cell to be written to.

9. The memory circuit as claimed in claim 7, wherein the bit line control circuit is adapted to put the primary sense amplifier into an active state, or to leave it in an active state, during writing of a strong value to a memory cell, the primary sense amplifier being associated with a bit line coupled to the memory cell to be written to.

10. The memory circuit as claimed in claim 1, the memory circuit comprising a precharge circuit adapted to precharge a bit line to a precharge level.

11. The memory circuit as claimed in claim 10, wherein the precharge level is between a first strong write level representing a first logic value, and a second strong write level representing a second logic value which differs from the first logic value.

12. The memory circuit as claimed in claim 11, wherein a weak write level is between a strong write level and the precharge level.

13. The memory circuit as claimed in claim 1, wherein the plurality of bit lines comprise at least a first bit line and a second bit line;
the bit line control circuit comprising a first bit line driver adapted to drive the first bit line to three different voltage levels as a function of at least one associated control signal;
the bit line control circuit comprising a second bit line driver adapted to drive the second bit line to three different voltage levels as a function of at least one associated control signal; and
the first bit line driver and the second bit line driver being adapted such that the first bit line driver may write a weak write level to the first bit line, whereas the second bit line driver writes a strong write level to the second bit line.

14. The memory circuit as claimed in claim 1, wherein the bit line control circuit is adapted to select a bit line driver of an individual bit line from a plurality of bit line drivers for driving the individual bit lines with a weak write level.

15. The memory circuit as claimed in claim 1, wherein the bit lines of the plurality of bit lines are arranged adjacently to one another on the memory chip.

16. The memory circuit as claimed in claim 1, wherein the bit lines of the plurality of bit lines are associated with a common word line.

17. A memory module comprising a memory circuit, the memory circuit comprising:
a plurality of bit lines;
a plurality of memory cells writable via a respective bit line; and
a bit line control circuit,
the bit line control circuit being configured to write, in a bit line-selective manner, a weak value to a memory cell coupled to a bit line selected.

18. The memory module as claimed in claim 17, wherein the memory circuit is arranged on a chip.

19. A data processing system, comprising:
a processor; and
a memory module comprising a memory circuit comprising:
a plurality of bit lines;
a plurality of memory cells writable via a respective bit line; and
a bit line control circuit,
the bit line control circuit being configured to write, in a bit line-selective manner, a weak value to a memory cell coupled to a bit line selected;
the processor being coupled to the memory module to read out data from the memory module or to write data to the memory module.

20. A memory circuit comprising:
a plurality of means for storing data;
a plurality of means for connecting the means for storing data to associated means for reading out data; and
means for selective writing of a weak value to a means for storing which is coupled to a selected means for connecting.

21. The memory circuit as claimed in claim 20, wherein the means for selective writing of a weak value comprises a means for applying a weak write level to a means for connecting.

22. The memory circuit as claimed in claim 20, wherein the means for the selective writing comprises a means for driving the means for connecting to at least three different signal levels.

23. The memory circuit as claimed in claim 20, wherein the means for selective writing comprises a means for generating a first strong write level or a second strong write level on the means for connecting in a first operating state; and
wherein the means for selective writing comprises a means for generating a strong write level or a weak write level on the means for connecting in a second operating state.

24. The memory circuit as claimed in claim 20, the memory circuit comprising a means for amplifying a potential difference existing between two means for connecting, and
the memory circuit comprising a means for deactivating the means for amplifying when a weak value is written to a means for storing.

25. A method for testing a memory circuit comprising a plurality of bit lines and a plurality of memory cells, the memory cells being writable via a respective bit line, and the method comprising:
bit line-selective writing of a weak value to a memory cell to be tested of the memory circuit; and
testing the memory cell to which the weak value has been written.

26. The method as claimed in claim 25, the method comprising writing a strong value to a memory cell adjacent to the memory cell to be tested, the adjacent memory cell being coupled to a different bit line than the memory cell to be tested.

27. The method as claimed in claim 25, the method comprising parallel provision of a weak write level on a first bit line, and of a strong write level on a second bit line, and
the method comprising activating a word line so as to write a weak value to a first memory cell in response to the activation of the word line on the basis of the weak write level, and to write a strong value to a second memory cell in response to the activation of the word line on the basis of the strong write level.

28. The method as claimed in claim 25, the method comprising switching the memory circuit from a normal operating mode to a test operating mode prior to the bit line-selective writing of a weak value,
at least one driver level of a bit line driver, which is coupled to a bit line in order to drive the bit line to an adjustable level, being modified by the switching from the normal operating mode to the test operating mode.

29. The method as claimed in claim 25, the testing of the memory cell to which the weak value has been written comprising verifying whether the value written to the memory cell to be tested may be read out in an error-free manner.

30. A memory circuit, comprising:
a plurality of bit lines;
a plurality of memory cells writable via a respective bit line;
a bit line control circuit adapted to write, in a bit line-selective manner, a weak value to a memory cell coupled to a bit line selected; and
a primary sense amplifier adapted to amplify a potential difference existing between two bit lines coupled to the primary sense amplifier;
wherein the bit line control circuit comprises a bit line driver adapted to drive, in a bit line-selective manner, a bit line to three different voltage levels as a function of a control signal;
the bit line control circuit being adapted to adjust the bit line driver such that the bit line driver drives a weak write level to the bit line selected during writing of a weak value; and
the bit line control circuit being adapted to deactivate the primary sense amplifier, or to leave it deactivated, during writing of a weak value.
